(19) United States
(12) Patent Application Publication
(10) Pub. No.: US 2026/0031114 A1
(43) Pub. Date: Jan. 29, 2026

(54) IMPEDANCE CALIBRATION IN A MEMORY SUB-SYSTEM

(71) Applicant: Micron Technology, Inc., Boise, ID (US)

(72) Inventors: Harsha Srirangam, Hyderabad (IN); Yui Shimizu, Livermore, CA (US); Kwangwon Kim, Milpitas, CA (US)

(21) Appl. No.: 19/266,845

(22) Filed: Jul. 11, 2025

Related U.S. Application Data
(60) Provisional application No. 63/674,478, filed on Jul. 23, 2024.

(51) Int. Cl. G11C 7/10; H03K 19/00

(52) U.S. Cl. CPC G11C 7/1012; G11C 7/1057; H03K 19/0005; G11C 2207/2254

(57) ABSTRACT

Control logic in a memory device initiates an impedance (ZQ) calibration to be performed by a calibration circuit coupled to an output buffer of an input/output circuit the I/O circuit of the memory device. A first set of calibration units of the calibration circuit includes a first calibration unit and a second calibration unit, where a first calibration code including a first sequence of bit values is generated having at least one bit value of the first sequence generated by a first transistor set of the first calibration unit and a second transistor set of the second calibration unit. The first calibration code is provided to one or more pull-up units of the output buffer, where the first calibration code is used to calibrate a first impedance of the one or more pull-up units. A second calibration code including a second sequence of bit values is generated by a second set of calibration units and a third set of calibration units. The second calibration code is provided to one or more pull-down units of the output buffer to calibrate a second impedance of the one or more pull-down units.

### CROSS-REFERENCE TO RELATED APPLICATION

This application claims the benefit of U.S. Provisional Application No. 63/674,478, titled “Impedance Calibration in a Memory Sub-system”, filed Jul. 23, 2024, which is hereby incorporated herein by reference in its entirety.

### TECHNICAL FIELD

Embodiments of the disclosure relate generally to memory sub-systems, and more specifically, relate to impedance calibration (ZQ calibration) in a memory sub-system.

### BACKGROUND

A memory sub-system can include one or more memory devices that store data. The memory devices can be, for example, non-volatile memory devices and volatile memory devices. In general, a host system can utilize a memory sub-system to store data at the memory devices and to retrieve data from the memory devices.

### BRIEF DESCRIPTION OF THE DRAWINGS

The present disclosure will be understood more fully from the detailed description given below and from the accompanying drawings of various embodiments of the disclosure.

FIG. 1A illustrates an example computing system that includes a memory sub-system, in accordance with one or more embodiments of the present disclosure.

FIG. 1B is a block diagram of a memory device in communication with a memory sub-system controller of a memory sub-system, in accordance with one or more embodiments of the present disclosure.

FIG. 2A-2C are schematics of portions of an array of memory cells as could be used in a memory of the type described with reference to FIG. 1B, in accordance with one or more embodiments of the present disclosure.

FIG. 3 is a block schematic of a portion of an array of memory cells as could be used in a memory of the type described with reference to FIG. 1B, in accordance with one or more embodiments of the present disclosure.

FIG. 4 illustrates embodiments of a calibration manager and ZQ calibration circuit to calibrate impedance associated with an output buffer of an input/output circuit of a memory device in a memory sub-system, in accordance with one or more embodiments of the present disclosure.

FIG. 5 illustrates embodiments of a calibration manager and ZQ calibration circuit to calibrate impedance associated with an output buffer of an input/output circuit of a memory device in a memory sub-system, in accordance with one or more embodiments of the present disclosure.

FIG. 6 illustrates embodiments of a calibration manager and ZQ calibration circuit to calibrate impedance associated with an output buffer of an input/output circuit of a memory device in a memory sub-system, in accordance with one or more embodiments of the present disclosure.

FIG. 7 illustrates embodiments of a calibration manager and ZQ calibration circuit to calibrate impedance associated with an output buffer of an input/output circuit of a memory device in a memory sub-system, in accordance with one or more embodiments of the present disclosure.

FIG. 8 is a flow diagram of an example ZQ calibration method, in accordance with one or more embodiments of the present disclosure.

FIG. 9 is a block diagram of an example computer system in which embodiments of the present disclosure can operate.

### DETAILED DESCRIPTION

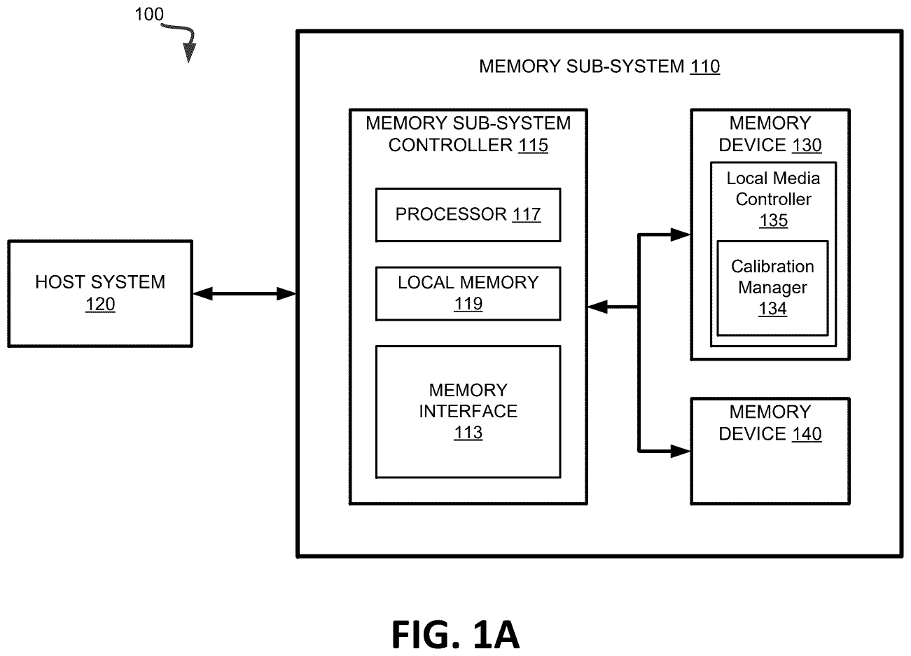

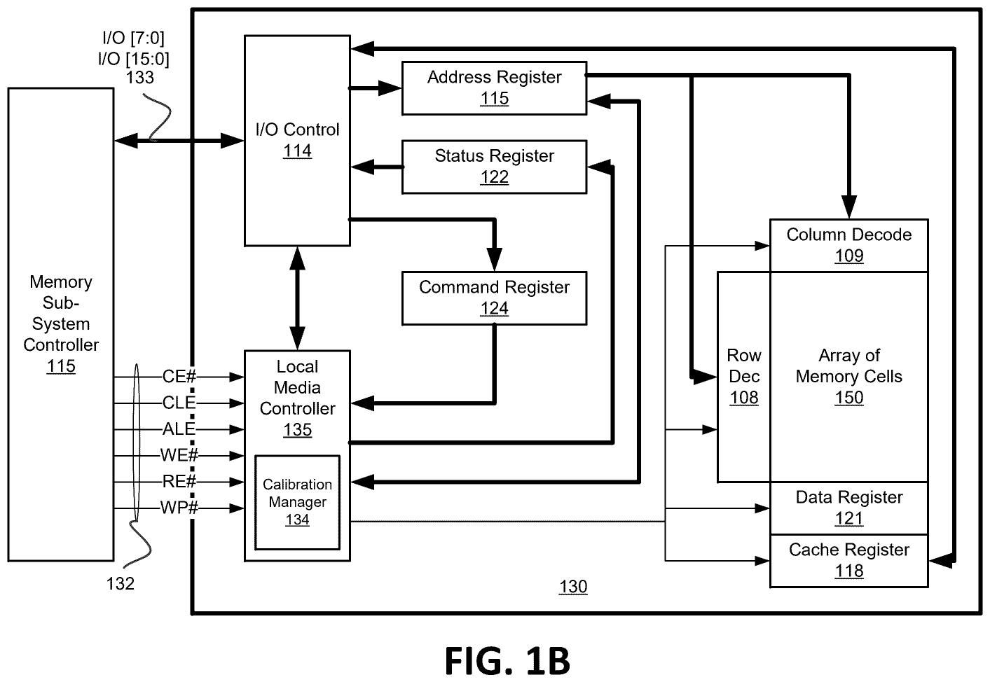

Aspects of the present disclosure are directed to impedance calibration (ZQ calibration) in a memory sub-system. A memory sub-system can be a storage device, a memory module, or a hybrid of a storage device and memory module. Examples of storage devices and memory modules are described below in conjunction with FIG. 1A. In general, a host system can utilize a memory sub-system that includes one or more components, such as memory devices that store data. The host system can provide data to be stored at the memory sub-system and can request data to be retrieved from the memory sub-system.

A memory sub-system can include high density non-volatile memory devices where retention of data is desired when no power is supplied to the memory device. One example of non-volatile memory devices is a negative-and (NAND) memory device. Other examples of non-volatile memory devices are described below in conjunction with FIG. 1A. A non-volatile memory device is a package of one or more dies. Each die can consist of one or more planes. For some types of non-volatile memory devices (e.g., NAND devices), each plane consists of a set of physical blocks. Each block consists of a set of pages. Each page consists of a set of memory cells (“cells”). A cell is an electronic circuit that stores information. Depending on the cell type, a cell can store one or more bits of binary information, and has various logic states that correlate to the number of bits being stored. The logic states can be represented by binary values, such as “0” and “1”, or combinations of such values.

Memory cells are formed on a silicon wafer in an array of columns (also hereinafter referred to as “bitlines”) and rows (also hereinafter referred to as wordlines). A wordline can refer to one or more rows of memory cells of a memory device that are used with one or more bitlines to generate the address of each of the memory cells. The intersection of a bitline and wordline constitutes the address of the memory cell.

A block hereinafter refers to a unit of the memory device used to store data and can include a group of memory cells, a wordline group, a wordline, or individual memory cells. Each block can include a number of sub-blocks, where each sub-block is defined by an associated pillar (e.g., a vertical conductive trace) extending from a shared bitline. Memory pages (also referred to herein as “pages”) store one or more bits of binary data corresponding to data received from the host system. To achieve high density, a string of memory cells in a non-volatile memory device can be constructed to include a number of memory cells at least partially surrounding a pillar of poly-silicon channel material (i.e., a channel region). The memory cells can be coupled to access lines (i.e., wordlines) often fabricated in common with the memory cells, so as to form an array of strings in a block of memory (e.g., a memory array). The compact nature of certain non-volatile memory devices, such as 3D flash NAND memory, means wordlines are common to many memory cells within a block of memory. Some memory devices use certain types of memory cells, such as triple-level cell (TLC) memory cells, which store three bits of data in each memory cell, which make it affordable to move more applications from legacy hard disk drives to newer memory sub-systems, such as NAND solid-state drives (SSDs).

The one or more memory devices of the memory sub-system may include memory cell arrays each having memory cells disposed at intersections between wordlines and bitlines. Various conditions in the memory device, such as operating temperatures and voltages in the power supply etc., may affect the performance of the memory device. In operation, various calibrations and adjustments are performed to ensure data is transferred accurately and reliably between the one or more memory devices and memory sub-system controller. These calibrations can include an impedance calibration (e.g., ZQ calibration) which can be periodically performed in the memory device to compensate for the variations of impedance of an input/output (I/O) circuit (e.g., changes in the impedance of an input/output (I/O) circuit due to varying power supply voltage or temperature).

The ZQ calibration process manages the termination of a memory bus associated with the one or more memory devices to prevent signal reflections and ensure data is transferred accurately. To perform the calibration, an impedance calibration command (e.g., a ZQ calibration command) may be periodically provided to a ZQ calibration circuit to perform an impedance calibration operation (e.g., a ZQ calibration operation). Periodically performing the calibration operation may compensate for variations of impedance of the I/O circuit due to voltage and/or temperature changes in the memory device.

In view of the calibration command, one or more ZQ calibration circuits provide an appropriate calibration code (also referred to as a “ZQ calibration code”) to a DQ output buffer of the I/O circuit based on the ZQ calibration results. Certain ZQ calibration systems employ a circuit (i.e., ZQ calibration circuit) to replicate the resistance of a corresponding component of the DQ output buffer (i.e., the pull-up circuit (e.g., PMOS circuit) and the pull-down circuit (e.g., NMOS circuit).

Each transistor of the calibration circuit has its own characteristics, and those characteristics can lead to mismatches in the resistance of the ZQ calibration circuits and the output buffer calibration circuits. The mismatched resistance can lead to the provisioning of an incorrect ZQ calibration code, which prevents proper impedance calibration. For example, the ZQ calibration circuits can include sets of transistors (e.g., a first set of eight transistors, a second set of four transistors, a third set of two transistors, a fourth set having one transistor, and a fifth set of two transistors to create and one-half stack) that are used to implement the binary coding of the ZQ calibration code. In this example, the fourth set which includes a single transistor can cause a weakness in the architecture since variations in the characteristics of this single transistor can have a bigger impact in the correspondence between the resistance levels of the ZQ calibration circuit and the DQ output buffer, leading to the generation of an incorrect ZQ calibration code.

According to aspects of the present disclosure, a memory sub-system is provided including impedance calibration circuits (herein referred to as “calibration units”) to perform ZQ calibration to generate ZQ calibration codes to be provided (i.e., copied) to a DQ output buffer of the memory sub-system. In an embodiment, a first set of calibration units are configured to generate a first ZQ calibration code to calibrate a pull-up circuit or unit of an output buffer of an input/output (I/O) circuit of the memory sub-system. In an embodiment, a second set of calibration units are configured to generate a second ZQ calibration code to calibrate a pull-down circuit of the output buffer. According to embodiments, each calibration unit includes an array of transistor sets, where each transistor set includes one or more transistors (e.g., one transistor, two transistors, four transistors, eight transistors, etc.) or a portion of a transistor (e.g., a one-half transistor, a one-quarter transistor, etc.) that are used to generate the ZQ calibration code.

According to embodiments, the first set of calibration units includes multiple calibration units (e.g., two calibration units), where each calibration unit includes an array of transistor sets. The respective array of transistor sets of the first calibration unit and the second calibration unit are used to generate a first ZQ calibration code used to calibrate the pull-up circuit of the output buffer.

According to embodiments, the second set of calibration units includes multiple calibration units (e.g., two calibration units), where each calibration unit includes an array of transistor sets. The respective array of transistor sets of the respective calibration units of the second set of calibration units are used to generate a second ZQ calibration code used to calibrate the pull-down circuit of the output buffer.

According to embodiments, the array of transistor sets of each calibration unit include a first transistor set of N transistors (e.g., N=8), a second transistor set of N/2 transistors, a third set of N/4 transistors, a fourth transistor set of N/8 transistors, a fifth set of N/16 transistors (e.g., a one-half transistor, where N=8), and a sixth set of N/32 transistors (e.g., a one-quarter transistor, where N=8).

Advantageously, the calibration units are configured such that no single transistor generates a corresponding bit value for the sequence of bits of the calibration code. For example, a particular bit value (e.g., a third bit value) is generated based on both an averaging of values generated by a first single transistor of a transistor set of a first calibration unit and a second single transistor of the corresponding transistor set of second calibration unit. Accordingly, the bit value is determined based on the two transistors (one from each of the respective transistor sets of the first calibration unit and the second calibration unit, respectively), which provides for robust and accurate coding since variations present with respect to the two individual transistors are offset by generating the bit value based on an average of the two transistors. This helps to reduce the effects of transistor variation that can lead to inaccurate coding when a bit value is based on a single transistor.

FIG. 1A illustrates an example computing system 100 that includes a memory sub-system 110 in accordance with some embodiments of the present disclosure. The memory sub-system 110 can include media, such as one or more volatile memory devices (e.g., memory device 140), one or more non-volatile memory devices (e.g., memory device 130), or a combination of such.

A memory sub-system 110 can be a storage device, a memory module, or a hybrid of a storage device and memory module. Examples of a storage device include a solid-state drive (SSD), a flash drive, a universal serial bus (USB) flash drive, an embedded Multi-Media Controller (eMMC) drive, a Universal Flash Storage (UFS) drive, a secure digital (SD) and a hard disk drive (HDD). Examples of memory modules include a dual in-line memory module (DIMM), a small outline DIMM (SO-DIMM), and various types of non-volatile dual in-line memory module (NVDIMM).

The computing system 100 can be a computing device such as a desktop computer, laptop computer, network server, mobile device, a vehicle (e.g., airplane, drone, train, automobile, or other conveyance), Internet of Things (IoT) enabled device, embedded computer (e.g., one included in a vehicle, industrial equipment, or a networked commercial device), or such computing device that includes memory and a processing device.

The computing system 100 can include a host system 120 that is coupled to one or more memory sub-systems 110. In some embodiments, the host system 120 is coupled to different types of memory sub-system 110. FIG. 1A illustrates one example of a host system 120 coupled to one memory sub-system 110. As used herein, “coupled to” or “coupled with” generally refers to a connection between components, which can be an indirect communicative connection or direct communicative connection (e.g., without intervening components), whether wired or wireless, including connections such as electrical, optical, magnetic, etc.

The host system 120 can include a processor chipset and a software stack executed by the processor chipset. The processor chipset can include one or more cores, one or more caches, a memory controller (e.g., NVDIMM controller), and a storage protocol controller (e.g., PCIe controller, SATA controller). The host system 120 uses the memory sub-system 110, for example, to write data to the memory sub-system 110 and read data from the memory sub-system 110.

The host system 120 can be coupled to the memory sub-system 110 via a physical host interface. Examples of a physical host interface include, but are not limited to, a serial advanced technology attachment (SATA) interface, a peripheral component interconnect express (PCIe) interface, universal serial bus (USB) interface, Fibre Channel, Serial Attached SCSI (SAS), a double data rate (DDR) memory bus, Small Computer System Interface (SCSI), a dual in-line memory module (DIMM) interface (e.g., DIMM socket interface that supports Double Data Rate (DDR)), etc. The physical host interface can be used to transmit data between the host system 120 and the memory sub-system 110. The host system 120 can further utilize an NVM Express (NVMe) interface to access components (e.g., memory devices 130) when the memory sub-system 110 is coupled with the host system 120 by the physical host interface (e.g., PCIe bus). The physical host interface can provide an interface for passing control, address, data, and other signals between the memory sub-system 110 and the host system 120. FIG. 1A illustrates a memory sub-system 110 as an example. In general, the host system 120 can access multiple memory sub-systems via a same communication connection, multiple separate communication connections, and/or a combination of communication connections.

The memory devices 130,140 can include any combination of the different types of non-volatile memory devices and/or volatile memory devices. The volatile memory devices (e.g., memory device 140) can be, but are not limited to, random access memory (RAM), such as dynamic random access memory (DRAM) and synchronous dynamic random access memory (SDRAM).

Some examples of non-volatile memory devices (e.g., memory device 130) include negative-and (NAND) type flash memory and write-in-place memory, such as a three-dimensional cross-point (“3D cross-point”) memory device, which is a cross-point array of non-volatile memory cells. A cross-point array of non-volatile memory can perform bit storage based on a change of bulk resistance, in conjunction with a stackable cross-gridded data access array. Additionally, in contrast to many flash-based memories, cross-point non-volatile memory can perform a write in-place operation, where a non-volatile memory cell can be programmed without the non-volatile memory cell being previously erased. NAND type flash memory includes, for example, two-dimensional NAND (2D NAND) and three-dimensional NAND (3D NAND).

Each of the memory devices 130 can include one or more arrays of memory cells. One type of memory cell, for example, single level cells (SLC) can store one bit per cell. Other types of memory cells, such as multi-level cells (MLCs), triple level cells (TLCs), quad-level cells (QLCs), and penta-level cells (PLCs) can store multiple bits per cell. In some embodiments, each of the memory devices 130 can include one or more arrays of memory cells such as SLCs, MLCs, TLCs, QLCs, or any combination of such. In some embodiments, a particular memory device can include an SLC portion, and an MLC portion, a TLC portion, a QLC portion, or a PLC portion of memory cells. The memory cells of the memory devices 130 can be grouped as pages that can refer to a logical unit of the memory device used to store data. With some types of memory (e.g., NAND), pages can be grouped to form blocks. In one embodiment, the term “MLC memory” can be used to represent any type of memory cell that stores more than one bit per cell (e.g., 2 bits, 3 bits, 4 bits, or 5 bits per cell).

Although non-volatile memory components such as 3D cross-point array of non-volatile memory cells and NAND type flash memory (e.g., 2D NAND, 3D NAND) are described, the memory device 130 can be based on any other type of non-volatile memory, such as read-only memory (ROM), phase change memory (PCM), self-selecting memory, other chalcogenide based memories, ferroelectric transistor random-access memory (FeTRAM), ferroelectric random access memory (FeRAM), magneto random access memory (MRAM), Spin Transfer Torque (STT)-MRAM, conductive bridging RAM (CBRAM), resistive random access memory (RRAM), oxide based RRAM (OxRAM), negative-or (NOR) flash memory, and electrically erasable programmable read-only memory (EEPROM).

A memory sub-system controller 115 (or controller 115 for simplicity) can communicate with the memory devices 130 to perform operations such as reading data, writing data, or erasing data at the memory devices 130 and other such operations. The memory sub-system controller 115 can include hardware such as one or more integrated circuits and/or discrete components, a buffer memory, or a combination thereof. The hardware can include a digital circuitry with dedicated (i.e., hard-coded) logic to perform the operations described herein. The memory sub-system controller 115 can be a microcontroller, special purpose logic circuitry (e.g., a field programmable gate array (FPGA), an application specific integrated circuit (ASIC), etc.), or other suitable processor.

The memory sub-system controller 115 can be a processing device, which includes one or more processors (e.g., processor 117), configured to execute instructions stored in a local memory 119. In the illustrated example, the local memory 119 of the memory sub-system controller 115 includes an embedded memory configured to store instructions for performing various processes, operations, logic flows, and routines that control operation of the memory sub-system 110, including handling communications between the memory sub-system 110 and the host system 120.

In some embodiments, the local memory 119 can include memory registers storing memory pointers, fetched data, etc. The local memory 119 can also include read-only memory (ROM) for storing micro-code. While the example memory sub-system 110 in FIG. 1A has been illustrated as including the memory sub-system controller 115, in another embodiment of the present disclosure, a memory sub-system 110 does not include a memory sub-system controller 115, and can instead rely upon external control (e.g., provided by an external host, or by a processor or controller separate from the memory sub-system).

In general, the memory sub-system controller 115 can receive commands or operations from the host system 120 and can convert the commands or operations into instructions or appropriate commands to achieve the desired access to the memory devices 130. The memory sub-system controller 115 can be responsible for other operations such as wear leveling operations, garbage collection operations, error detection and error-correcting code (ECC) operations, encryption operations, caching operations, and address translations between a logical address (e.g., logical block address (LBA), namespace) and a physical address (e.g., physical block address) that are associated with the memory devices 130. The memory sub-system controller 115 can further include host interface circuitry to communicate with the host system 120 via the physical host interface. The host interface circuitry can convert the commands received from the host system into command instructions to access the memory devices 130 as well as convert responses associated with the memory devices 130 into information for the host system 120.

The memory sub-system 110 can also include additional circuitry or components that are not illustrated. In some embodiments, the memory sub-system 110 can include a cache or buffer (e.g., DRAM) and address circuitry (e.g., a row decoder and a column decoder) that can receive an address from the memory sub-system controller 115 and decode the address to access the memory devices 130.

In some embodiments, the memory devices 130 include local media controllers 135 that operate in conjunction with memory sub-system controller 115 to execute operations on one or more memory cells of the memory devices 130. An external controller (e.g., memory sub-system controller 115) can externally manage the memory device 130 (e.g., perform media management operations on the memory device 130). In some embodiments, memory sub-system 110 is a managed memory device, which includes a raw memory device 130 having control logic (e.g., local media controller 135) on the die and a controller (e.g., memory sub-system controller 115) for media management within the same memory device package. An example of a managed memory device is a managed NAND (MNAND) device.

In one embodiment, the memory sub-system 110 includes a memory interface component 113. Memory interface component 113 is responsible for handling interactions of memory sub-system controller 115 with the memory devices of memory sub-system 110, such as memory device 130. For example, memory interface component 113 can send memory access commands corresponding to requests received from host system 120 to memory device 130, such as program commands, read commands, or other commands. In addition, memory interface component 113 can receive data from memory device 130, such as data retrieved in response to a read command or a confirmation that a program command was successfully performed. For example, the memory sub-system controller 115 can include a processor 117 (processing device) configured to execute instructions stored in local memory 119 for performing the operations described herein.

In one embodiment, memory device 130 includes a calibration manager 134 configured to carry out corresponding memory access operations, in response to receiving the memory access commands from memory interface 113. In some embodiments, local media controller 135 includes at least a portion of calibration manager 134 and is configured to perform the functionality described herein. In some embodiments, calibration manager 134 is implemented on memory device 130 using firmware, hardware components, or a combination of the above. In one embodiment, calibration manager 134 receives, from a requestor, such as memory interface 113, a request to program data to a memory array of memory device 130. The memory array can include an array of memory cells formed at the intersections of wordlines and bitlines. In one embodiment, the memory cells are grouped in to blocks, which can be further divided into sub-blocks, where a given wordline is shared across a number of sub-blocks, for example. In one embodiment, each sub-block corresponds to a separate plane in the memory array. The group of memory cells associated with a wordline within a sub-block is referred to as a physical page. In one embodiment, there can be multiple portions of the memory array, such as a first portion where the sub-blocks are configured as SLC memory and a second portion where the sub-blocks are configured as multi-level cell (MLC) memory (i.e., including memory cells that can store two or more bits of information per cell). For example, the second portion of the memory array can be configured as TLC memory. The voltage levels of the memory cells in TLC memory form a set of 8 programming distributions representing the 8 different combinations of the three bits stored in each memory cell. Depending on how the memory cells are configured, each physical page in one of the sub-blocks can include multiple page types. For example, a physical page formed from single level cells (SLCs) has a single page type referred to as a lower logical page (LP). Multi-level cell (MLC) physical page types can include LPs and upper logical pages (UPs), TLC physical page types are LPs, UPs, and extra logical pages (XPs), and QLC physical page types are LPs, UPs, XPs and top logical pages (TPs). For example, a physical page formed from memory cells of the QLC memory type can have a total of four logical pages, where each logical page can store data distinct from the data stored in the other logical pages associated with that physical page.

In one embodiment, calibration manager 134 can execute commands to cause a ZQ calibration circuit to generate ZQ calibration codes to calibrate pull-up units and pull-down units of the output buffer of an I/O circuit of a memory device. In an embodiment, the calibration manager 134 and ZQ calibration circuit cause a first ZQ calibration code to be copied or provided to one or more pull-up units of the output buffer. In an embodiment, the calibration manager 134 and ZQ calibration circuit cause a second ZQ calibration code to be copied or provided to one or more pull-down units of the output buffer. Further details with regards to the operations of calibration manager 134 and ZQ calibration circuit are described below.

FIG. 1B is a simplified block diagram of a first apparatus, in the form of a memory device 130, in communication with a second apparatus, in the form of a memory sub-system controller 115 of a memory sub-system (e.g., memory sub-system 110 of FIG. 1A), according to an embodiment. Some examples of electronic systems include personal computers, personal digital assistants (PDAs), digital cameras, digital media players, digital recorders, games, appliances, vehicles, wireless devices, mobile telephones and the like. The memory sub-system controller 115 (e.g., a controller external to the memory device 130), may be a memory controller or other external host device.

Memory device 130 includes an array of memory cells 150 logically arranged in rows and columns. Memory cells of a logical row are typically connected to the same access line (e.g., a wordline) while memory cells of a logical column are typically selectively connected to the same data line (e.g., a bitline). A single access line may be associated with more than one logical row of memory cells and a single data line may be associated with more than one logical column. Memory cells (not shown in FIG. 1B) of at least a portion of array of memory cells 250 are capable of being programmed to one of at least two target data states.

Row decode circuitry 108 and column decode circuitry 109 are provided to decode address signals. Address signals are received and decoded to access the array of memory cells 150. Memory device 130 also includes input/output (I/O) control circuitry (or I/O circuit) 114 to manage input of commands, addresses and data to the memory device 130 as well as output of data and status information from the memory device 130. An address register 115 is in communication with I/O control circuitry 114 and row decode circuitry 108 and column decode circuitry 109 to latch the address signals prior to decoding. A command register 124 is in communication with I/O control circuitry 114 and local media controller 135 to latch incoming commands.

A controller (e.g., the local media controller 135 internal to the memory device 130) controls access to the array of memory cells 150 in response to the commands and generates status information for the external memory sub-system controller 115, i.e., the local media controller 135 is configured to perform access operations (e.g., read operations, programming operations and/or erase operations) on the array of memory cells 150. The local media controller 135 is in communication with row decode circuitry 108 and column decode circuitry 110 to control the row decode circuitry 108 and column decode circuitry 110 in response to the addresses. In one embodiment, local media controller 135 includes calibration manager 134, which can implement a ZQ calibration process to calibrate impedance of an output buffer of the I/O control 114, as described herein.

The local media controller 135 is also in communication with a cache register 118. Cache register 118 latches data, either incoming or outgoing, as directed by the local media controller 135 to temporarily store data while the array of memory cells 150 is busy writing or reading, respectively, other data. During a program operation (e.g., write operation), data may be passed from the cache register 118 to the data register 121 for transfer to the array of memory cells 150; then new data may be latched in the cache register 118 from the I/O control circuitry 212. During a read operation, data may be passed from the cache register 118 to the I/O control circuitry 114 for output to the memory sub-system controller 115; then new data may be passed from the data register 121 to the cache register 118. The cache register 118 and/or the data register 121 may form (e.g., may form a portion of) a page buffer of the memory device 130. A page buffer may further include sensing devices (not shown in FIG. 1B) to sense a data state of a memory cell of the array of memory cells 150, e.g., by sensing a state of a data line connected to that memory cell. A status register 122 may be in communication with I/O control circuitry 114 and the local memory controller 135 to latch the status information for output to the memory sub-system controller 115.

Memory device 130 receives control signals at the memory sub-system controller 115 from the local media controller 135 over a control link 132. For example, the control signals can include a chip enable signal CE #, a command latch enable signal CLE, an address latch enable signal ALE, a write enable signal WE #, a read enable signal RE #, and a write protect signal WP #. Additional or alternative control signals (not shown) may be further received over control link 132 depending upon the nature of the memory device 130. In one embodiment, memory device 130 receives command signals (which represent commands), address signals (which represent addresses), and data signals (which represent data) from the memory sub-system controller 115 over a multiplexed input/output (I/O) bus 133 and outputs data to the memory sub-system controller 115 over I/O bus 133.

For example, the commands may be received over input/output (I/O) pins [7:0] of I/O bus 133 at I/O control circuitry 114 and may then be written into command register 124. The addresses may be received over input/output (I/O) pins [7:0] of I/O bus 234 at I/O control circuitry 114 and may then be written into address register 115. The data may be received over input/output (I/O) pins [7:0] for an 8-bit device or input/output (I/O) pins [15:0] for a 16-bit device at I/O control circuitry 114 and then may be written into cache register 118. The data may be subsequently written into data register 121 for programming the array of memory cells 150.

In an embodiment, cache register 118 may be omitted, and the data may be written directly into data register 121. Data may also be output over input/output (I/O) pins [7:0] for an 8-bit device or input/output (I/O) pins [15:0] for a 16-bit device. Although reference may be made to I/O pins, they may include any conductive node providing for electrical connection to the memory device 130 by an external device (e.g., the memory sub-system controller 115), such as conductive pads or conductive bumps as are commonly used.

It will be appreciated by those skilled in the art that additional circuitry and signals can be provided, and that the memory device 130 of FIG. 1B has been simplified. It should be recognized that the functionality of the various block components described with reference to FIG. 1B may not necessarily be segregated to distinct components or component portions of an integrated circuit device. For example, a single component or component portion of an integrated circuit device could be adapted to perform the functionality of more than one block component of FIG. 1B. Alternatively, one or more components or component portions of an integrated circuit device could be combined to perform the functionality of a single block component of FIG. 1B. Additionally, while specific I/O pins are described in accordance with popular conventions for receipt and output of the various signals, it is noted that other combinations or numbers of I/O pins (or other I/O node structures) may be used in the various embodiments.

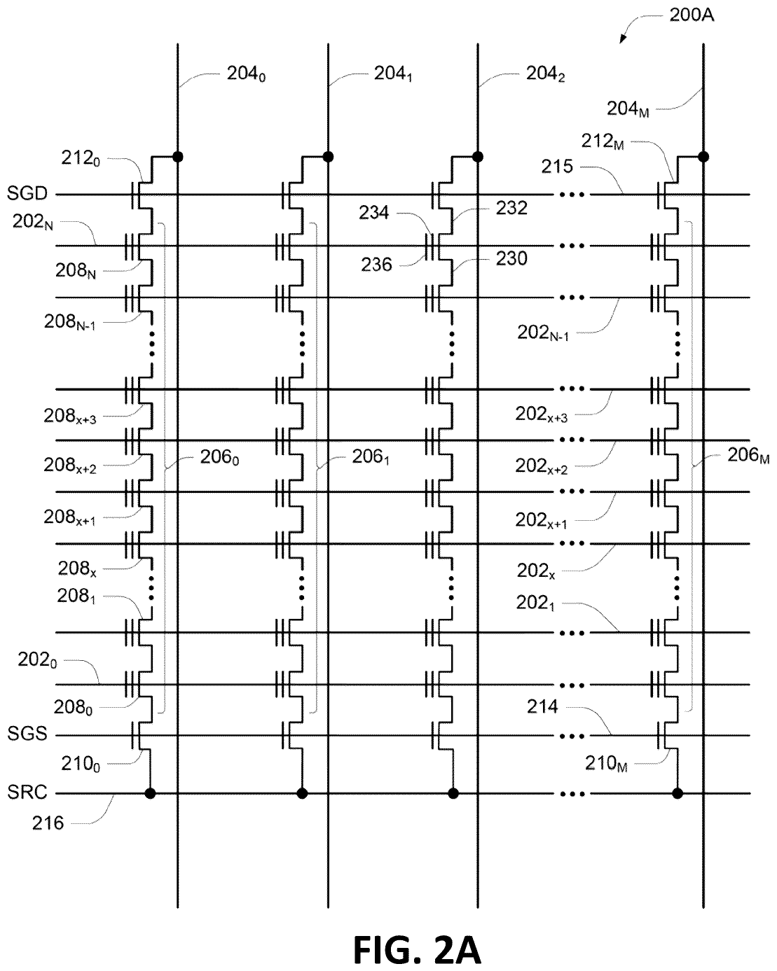

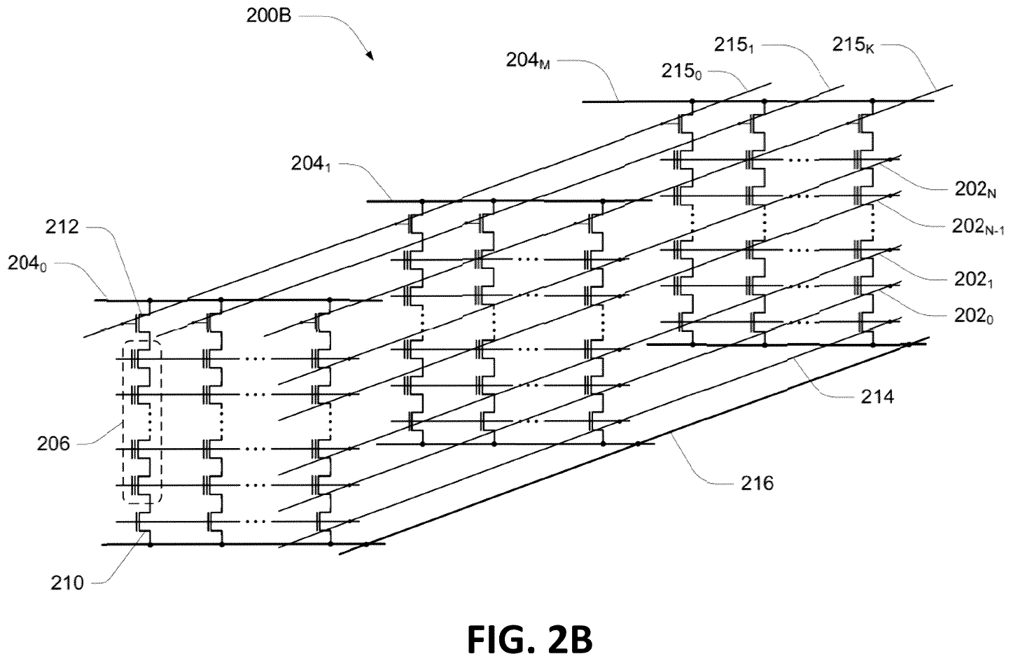

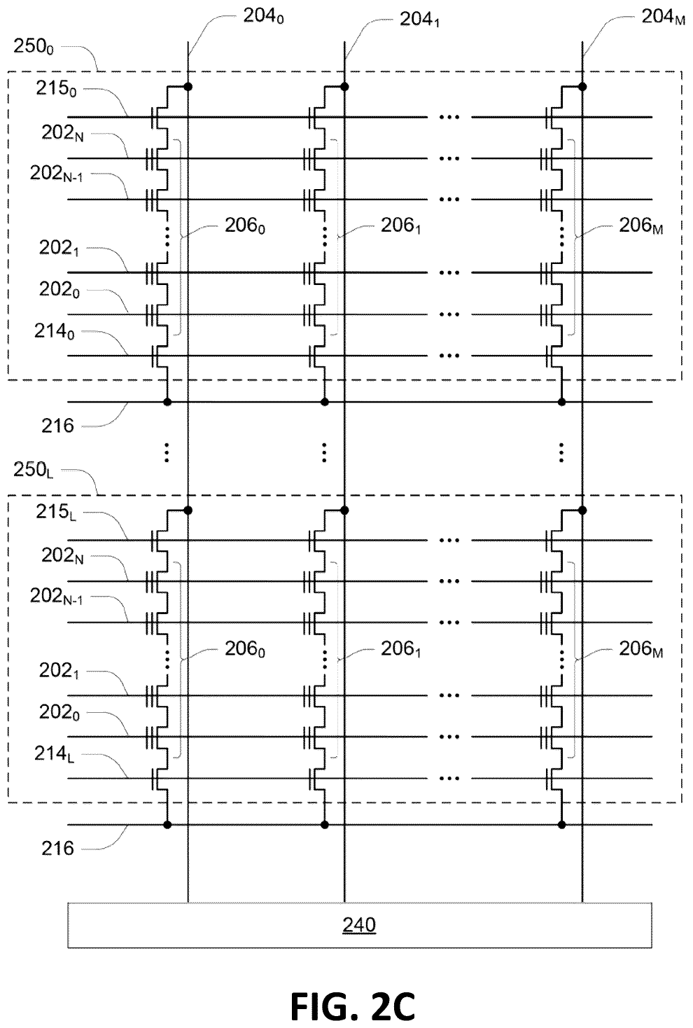

FIG. 2A-2C are schematics of portions of an array of memory cells 200A, such as a NAND memory array, as could be used in a memory of the type described with reference to FIG. 1B according to an embodiment, e.g., as a portion of the array of memory cells 104. Memory array 200A includes access lines, such as wordlines 202₀ to 202_{N}, and data lines, such as bitlines 204₀ to 204_{M}. The wordlines 202 can be connected to global access lines (e.g., global wordlines), not shown in FIG. 2A, in a many-to-one relationship. For some embodiments, memory array 200A can be formed over a semiconductor that, for example, can be conductively doped to have a conductivity type, such as a p-type conductivity, e.g., to form a p-well, or an n-type conductivity, e.g., to form an n-well.

Memory array 200A can be arranged in rows (each corresponding to a wordline 202) and columns (each corresponding to a bitline 204). Each column can include a string of series-connected memory cells (e.g., non-volatile memory cells), such as one of NAND strings 206₀ to 206_{M}. Each NAND string 206 can be connected (e.g., selectively connected) to a common source (SRC) 216 and can include memory cells 208₀ to 208_{N}. The memory cells 208 can represent non-volatile memory cells for storage of data. The memory cells 208 of each NAND string 206 can be connected in series between a select gate 210 (e.g., a field-effect transistor), such as one of the select gates 210₀ to 210_{M} (e.g., that can be source select transistors, commonly referred to as select gate source), and a select gate 212 (e.g., a field-effect transistor), such as one of the select gates 212₀ to 212_{M} (e.g., that can be drain select transistors, commonly referred to as select gate drain). Select gates 210₀ to 210_{M} can be commonly connected to a select line 214, such as a source select line (SGS), and select gates 212₀ to 212_{M} can be commonly connected to a select line 215, such as a drain select line (SGD). Although depicted as traditional field-effect transistors, the select gates 210 and 212 can utilize a structure similar to (e.g., the same as) the memory cells 208. The select gates 210 and 212 can represent a number of select gates connected in series, with each select gate in series configured to receive a same or independent control signal.

A source of each select gate 210 can be connected to common source 216. The drain of each select gate 210 can be connected to a memory cell 208₀ of the corresponding NAND string 206. For example, the drain of select gate 210₀ can be connected to memory cell 208₀ of the corresponding NAND string 206₀. Therefore, each select gate 210 can be configured to selectively connect a corresponding NAND string 206 to the common source 216. A control gate of each select gate 210 can be connected to the select line 214.

The drain of each select gate 212 can be connected to the bitline 204 for the corresponding NAND string 206. For example, the drain of select gate 212₀ can be connected to the bitline 204₀ for the corresponding NAND string 206₀. The source of each select gate 212 can be connected to a memory cell 208_{N} of the corresponding NAND string 206. For example, the source of select gate 212₀ can be connected to memory cell 208_{N} of the corresponding NAND string 206₀. Therefore, each select gate 212 can be configured to selectively connect a corresponding NAND string 206 to the corresponding bitline 204. A control gate of each select gate 212 can be connected to select line 215.

The memory array 200A in FIG. 2A can be a quasi-two-dimensional memory array and can have a generally planar structure, e.g., where the common source 216, NAND strings 206 and bitlines 204 extend in substantially parallel planes. Alternatively, the memory array 200A in FIG. 2A can be a three-dimensional memory array, e.g., where NAND strings 206 can extend substantially perpendicular to a plane containing the common source 216 and to a plane containing the bitlines 204 that can be substantially parallel to the plane containing the common source 216.

Typical construction of memory cells 208 includes a data-storage structure 234 (e.g., a floating gate, charge trap, and the like) that can determine a data state of the memory cell (e.g., through changes in threshold voltage), and a control gate 236, as shown in FIG. 2A. The data-storage structure 234 can include both conductive and dielectric structures while the control gate 236 is generally formed of one or more conductive materials. In some cases, memory cells 208 can further have a defined source/drain (e.g., source) 230 and a defined source/drain (e.g., drain) 232. The memory cells 208 have their control gates 236 connected to (and in some cases form) a wordline 202.

A column of the memory cells 208 can be a NAND string 206 or a number of NAND strings 206 selectively connected to a given bitline 204. A row of the memory cells 208 can be memory cells 208 commonly connected to a given wordline 202. A row of memory cells 208 can, but need not, include all the memory cells 208 commonly connected to a given wordline 202. Rows of the memory cells 208 can often be divided into one or more groups of physical pages of memory cells 208, and physical pages of the memory cells 208 often include every other memory cell 208 commonly connected to a given wordline 202. For example, the memory cells 208 commonly connected to wordline 202_{N} and selectively connected to even bitlines 204 (e.g., bitlines 204₀, 204₂, 204₄, etc.) can be one physical page of the memory cells 208 (e.g., even memory cells) while memory cells 208 commonly connected to wordline 202_{N} and selectively connected to odd bitlines 204 (e.g., bitlines 204₁, 204₃, 204₅, etc.) can be another physical page of the memory cells 208 (e.g., odd memory cells).

Although bitlines 204₃-204₅ are not explicitly depicted in FIG. 2A, it is apparent from the figure that the bitlines 204 of the array of memory cells 200A can be numbered consecutively from bitline 204₀ to bitline 204_{M}. Other groupings of the memory cells 208 commonly connected to a given wordline 202 can also define a physical page of memory cells 208. For certain memory devices, all memory cells commonly connected to a given wordline can be deemed a physical page of memory cells. The portion of a physical page of memory cells (which, in some embodiments, could still be the entire row) that is read during a single read operation or programmed during a single programming operation (e.g., an upper or lower page of memory cells) can be deemed a logical page of memory cells. A block of memory cells can include those memory cells that are configured to be erased together, such as all memory cells connected to wordlines 202₀-202_{N} (e.g., all NAND strings 206 sharing common wordlines 202). Unless expressly distinguished, a reference to a page of memory cells herein refers to the memory cells of a logical page of memory cells. Although the example of FIG. 2A is discussed in conjunction with NAND flash, the embodiments and concepts described herein are not limited to a particular array architecture or structure, and can include other structures (e.g., SONOS, phase change, ferroelectric, etc.) and other architectures (e.g., AND arrays, NOR arrays, etc.).

FIG. 2B is another schematic of a portion of an array of memory cells 200B as could be used in a memory of the type described with reference to FIG. 1B, e.g., as a portion of the array of memory cells 104. Like numbered elements in FIG. 2B correspond to the description as provided with respect to FIG. 2A. FIG. 2B provides additional detail of one example of a three-dimensional NAND memory array structure. The three-dimensional NAND memory array 200B can incorporate vertical structures which can include semiconductor pillars where a portion of a pillar can act as a channel region of the memory cells of NAND strings 206. The NAND strings 206 can be each selectively connected to a bitline 204₀-204_{M} by a select transistor 212 (e.g., that can be drain select transistors, commonly referred to as select gate drain) and to a common source 216 by a select transistor 210 (e.g., that can be source select transistors, commonly referred to as select gate source). Multiple NAND strings 206 can be selectively connected to the same bitline 204. Subsets of NAND strings 206 can be connected to their respective bitlines 204 by biasing the select lines 215₀-215_{K} to selectively activate particular select transistors 212 each between a NAND string 206 and a bitline 204. The select transistors 210 can be activated by biasing the select line 214. Each wordline 202 can be connected to multiple rows of memory cells of the memory array 200B. Rows of memory cells that are commonly connected to each other by a particular wordline 202 can collectively be referred to as tiers.

FIG. 2C is a further schematic of a portion of an array of memory cells 200C as could be used in a memory of the type described with reference to FIG. 1B, e.g., as a portion of the array of memory cells 104. Like numbered elements in FIG. 2C correspond to the description as provided with respect to FIG. 2A. The array of memory cells 200C can include strings of series-connected memory cells (e.g., NAND strings) 206, access (e.g., word) lines 202, data (e.g., bit) lines 204, select lines 214 (e.g., source select lines), select lines 215 (e.g., drain select lines) and a source 216 as depicted in FIG. 2A. A portion of the array of memory cells 200A can be a portion of the array of memory cells 200C, for example.

FIG. 2C depicts groupings of NAND strings 206 into blocks of memory cells 250, e.g., blocks of memory cells 250₀-250_{L}. Blocks of memory cells 250 can be groupings of memory cells 208 that can be erased together in a single erase operation, sometimes referred to as erase blocks. Each block of memory cells 250 can represent those NAND strings 206 commonly associated with a single select line 215, e.g., select line 215₀. The source 216 for the block of memory cells 250₀ can be a same source as the source 216 for the block of memory cells 250_{L}. For example, each block of memory cells 250₀-250_{L} can be commonly selectively connected to the source 216. Access lines 202 and select lines 214 and 215 of one block of memory cells 250 can have no direct connection to access lines 202 and select lines 214 and 215, respectively, of any other block of memory cells of the blocks of memory cells 250₀-250_{L}.

The bitlines 204₀-204_{M} can be connected (e.g., selectively connected) to a buffer portion 240, which can be a portion of the page buffer 152 of the memory device 130. The buffer portion 240 can correspond to a memory plane (e.g., the set of blocks of memory cells 250₀-250_{L}). The buffer portion 240 can include sense circuits (which can include sense amplifiers) for sensing data values indicated on respective bitlines 204.

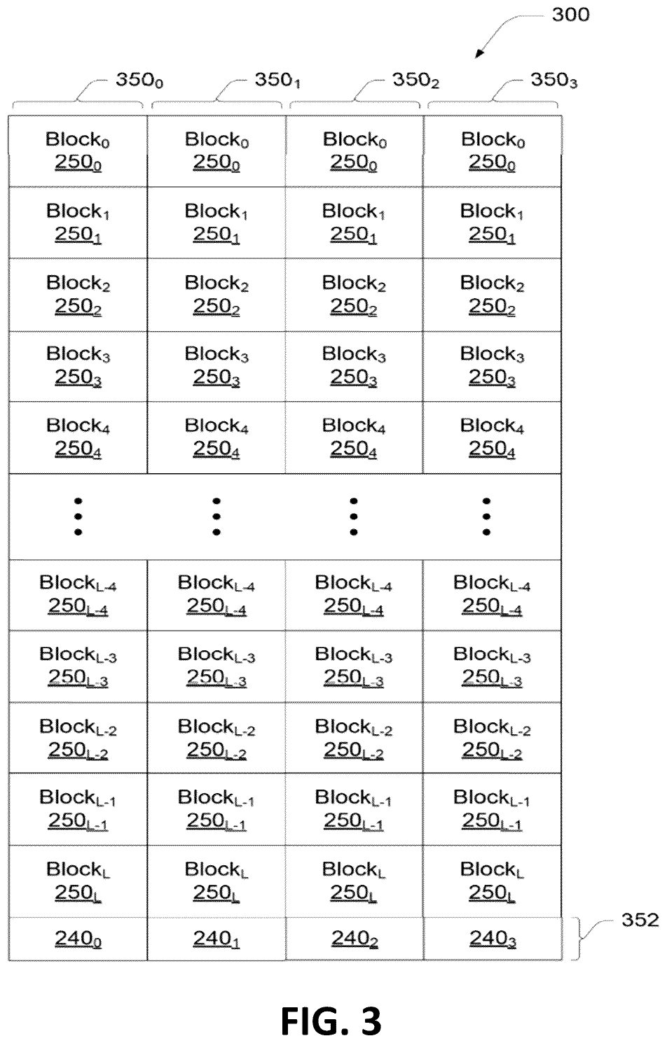

FIG. 3 is a block schematic of a portion of an array of memory cells 300 as could be used in a memory of the type described with reference to FIG. 1B. The array of memory cells 300 is depicted as having four memory planes 350 (e.g., memory planes 350₀-350₃), each in communication with a respective buffer portion 240, which can collectively form a page buffer 352. While four memory planes 350 are depicted, other numbers of memory planes 350 can be commonly in communication with a page buffer 352. Each memory plane 350 is depicted to include L+1 blocks of memory cells 250 (e.g., blocks of memory cells 250₀-250_{L}).

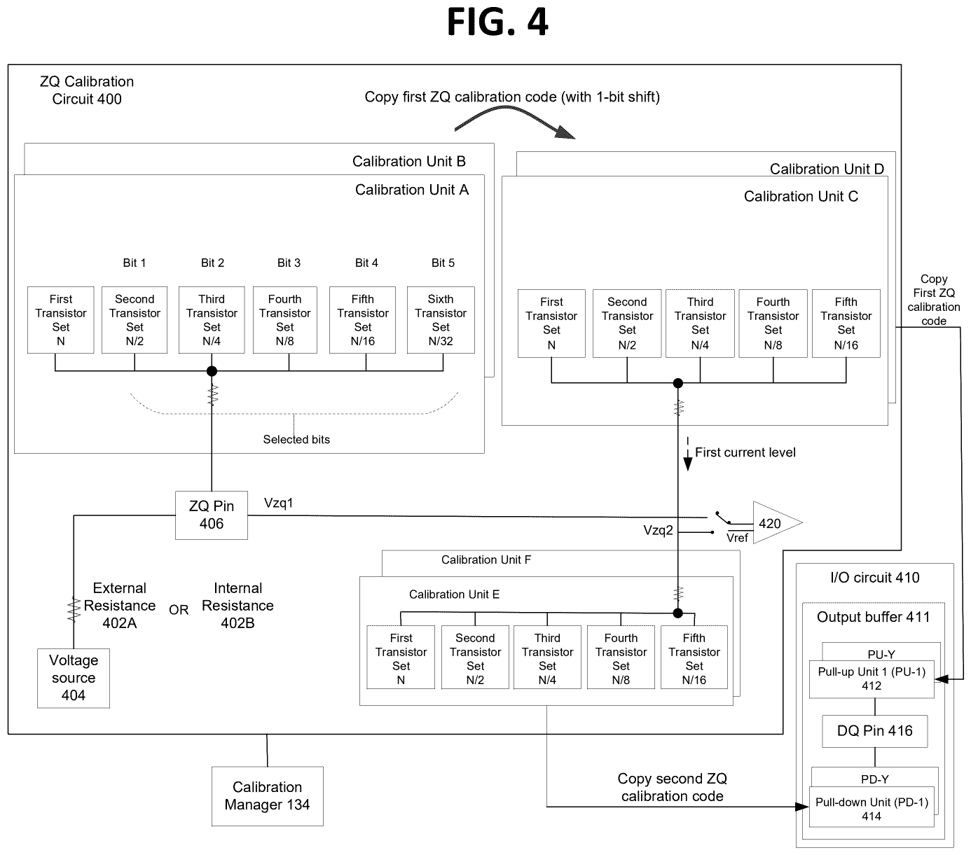

FIG. 4 illustrates an example impedance (ZQ) calibration control circuit 400 of a memory sub-system, according to an embodiment of the present disclosure. FIG. 4 illustrates a calibration manager 134 to control operation of the ZQ calibration control circuit 400 configured to perform ZQ calibration of a memory device of a memory sub-system. According to an embodiment, as shown in FIG. 4, the calibration manager 134 sends one or more commands to the ZQ calibration circuit 400 to cause the calibration units (e.g., calibration unit A, calibration unit B, calibration unit C, calibration unit D, calibration unit E, and calibration unit F) to perform ZQ calibration to generate ZQ calibration codes (e.g., a sequence of binary bits, such as 00000, 00001, 10000, 11000, etc.) to be provided (i.e., copied) to an output buffer 411 (e.g., a data (DQ) output buffer) of an input/output (I/O) circuit 410 of the memory sub-system. In an embodiment, the ZQ calibration code represents calibration parameters that are supplied to respective pull-up units and pull-down units of the output buffer 411 of the I/O circuit 410 to set the programmable termination components (i.e., the pull-up units and pull-down units) to the desired impedance for the output buffer 411 of the I/O circuit 410.

According to embodiments, the output buffer 411 of the memory sub-system includes data (DQ) circuitry to receive data transactions from a memory sub-system controller via a DQ bus coupled to one or more DQ pins representing a set of DQ lines. According to embodiments, the output buffer 411 includes a data input terminal DQ 416 and a set of pull-up units 412 (e.g., PU-1 to PU-Y and a set of pull-down units 414 (e.g., PD-1 to PD-Y). In an embodiment, output nodes of the pull-up units 412 and pull-down units 414 are coupled in common to a corresponding data input/output terminal via resistors. In an embodiment, the pull-up units 412 (e.g., pull-up unit 1 to pull-up unit Y, where Y equals 8) have the same circuit configuration and are collectively referred to as pull-up units 412. Similarly, the pull-down units (e.g., pull-down unit 1 to pull-down unit Y, where Y equals 8) have the same circuit configuration and are collectively referred to as pull-down units 414.

According to embodiments, corresponding pull-up units and the pull-down units are paired. According to embodiments, the impedance of each of the activated pull-up units 412 is specified by the first ZQ calibration code and the impedance of each of the activated pull-down units 414 is specified by the second ZQ calibration code.

In the embodiment shown in FIG. 4, each calibration unit has a resistance rating or level (e.g., a 300 ohm unit, a 600 ohm unit, etc.). In an embodiment of the ZQ calibration circuit 400 shown in FIG. 4, an external resistance 402A is provided having a resistance value (e.g., 300 ohms) generated by a voltage source 404 supplying a voltage (e.g., VSS) to generate a reference impedance that is coupled to a calibration terminal or pin (ZQ pin 406). According to embodiments, the calibration manager 134 is configured to perform ZQ calibration using the external resistance 402A to establish a match between the resistance or impedance levels of the ZQ pin and the DQ pin of the output buffer 411.

In another embodiment of the ZQ calibration circuit 400 shown in FIG. 4, an internal resistance 402B (e.g., on memory die resistance) is provided having a resistance value (e.g., 300 ohms) generated by a voltage source 404 supplying a voltage (e.g., VSS) to generate a reference impedance that is coupled to a calibration terminal or pin (ZQ pin 406). According to embodiments, the calibration manager 134 is configured to perform ZQ calibration using the internal resistance 402B to establish a match between the resistance or impedance levels of the ZQ pin and the DQ pin of the output buffer 411.

In an embodiment, a first set of calibration units (e.g., calibration unit A and calibration unit B) are configured to generate a first ZQ calibration code that is used to calibrate a pull-up unit 412 of the output buffer 411 of the memory sub-system. In an embodiment, a second set of calibration units (e.g., calibration unit C, calibration unit D) and a third set of calibration units (e.g., calibration unit E and calibration unit F) are configured to generate a second ZQ calibration code to calibrate respective pull-down units 414 of the output buffer 411 of the I/O circuit 410.

According to the embodiment of FIG. 4, each calibration unit includes an array of transistor sets, where each transistor set includes one or more transistors (e.g., one transistor, two transistors, four transistors, eight transistors, etc.) or a portion of a transistor (e.g., a one-half transistor, a one-quarter transistor, etc.) that are used to generate respective bits of a corresponding ZQ calibration code.

According to the embodiment of FIG. 4, the first set of calibration units includes calibration unit A and calibration unit B, where each calibration unit includes an array of transistor sets (e.g., first transistor set, second transistor set . . . and sixth transistor set). According to the embodiment of FIG. 4, the first transistor set of calibration unit A and calibration unit B includes N number of transistors. In the example shown in FIG. 4, N equals 8. In the example shown in FIG. 4, the second transistor set of calibration unit A and calibration unit B includes N/2 number of transistors (e.g., 4 transistors). In the example shown in FIG. 4, the third transistor set of calibration unit A and calibration unit B includes N/4 number of transistors (e.g., 2 transistors). In the example shown in FIG. 4, the fourth transistor set of calibration unit A and calibration unit B includes N/8 number of transistors (e.g., 1 transistor). In the example shown in FIG. 4, the fifth transistor set of calibration unit A and calibration unit B includes N/16 number of transistors (e.g., a one-half transistor). In the example shown in FIG. 4, the sixth transistor set of calibration unit A and calibration unit B includes N/32 number of transistors (e.g., a one-quarter transistor). In the embodiment shown in FIG. 4, the first set of calibration units are “extended” to include the sixth transistor set, as compared to the pull-up units 412 and pull-down units 414 that include five transistor sets (e.g., a first transistor set of N transistors, a second transistor set of N/2 transistors, a third transistor set of N/4 transistors, a fourth transistor set of N/8 transistors, and a fifth transistor set of N/16 transistors).

In an embodiment, the calibration manager 134 sends a calibration command to the first set of calibration units (e.g., calibration unit A and calibration unit B) (e.g., using a ZQ pin associated with the memory device) to cause the first set of calibration units to generate the first ZQ calibration code (e.g., a five-bit binary sequence). In the embodiment shown in FIG. 4, a first bit (Bit 1) of the first ZQ calibration code is generated by the respective second transistor sets of calibration unit A and calibration unit B. In the embodiment shown in FIG. 4, a second bit (Bit 2) of the first ZQ calibration code is generated by the respective third transistor sets of calibration unit A and calibration unit B. In the embodiment shown in FIG. 4, a third bit (Bit 3) of the first ZQ calibration code is generated by the respective fourth transistor sets of calibration unit A and calibration unit B. In the embodiment shown in FIG. 4, a fourth bit (Bit 4) of the first ZQ calibration code is generated by the respective fifth transistor sets of calibration unit A and calibration unit B. In the embodiment shown in FIG. 4, a fifth bit (Bit 5) of the first ZQ calibration code is generated by the respective sixth transistor sets of calibration unit A and calibration unit B.

Advantageously, the third bit (Bit 3) is generated based on both a first single transistor of the fourth transistor set of calibration unit A and a second single transistor of the fourth transistor set of calibration unit B. Accordingly, the third bit value is determined based on the two transistors (one from each of the respective fourth transistor sets of calibration unit A and calibration unit B, respectively), which provides for robust and accurate coding since variations present with respect to the two individual transistors are offset by generating the bit value based on an average of the two transistors. This helps to reduce the effects of transistor variation that can lead to inaccurate coding when a bit value is based on a single transistor.

In the embodiment shown in FIG. 4, the first ZQ calibration code (e.g., Bit 1 through Bit 5) generated by the first set of calibration units (calibration unit A and calibration unit B) is copied to the second set of calibration units (e.g., calibration unit C and calibration unit D), which in turn copies or provides to the I/O circuit 410 for use in calibrating a respective pull-up unit 412 of the set of pull-up units of the output buffer 411 of the I/O circuit 410. According to embodiments, the impedance of the respective pull-up unit 412 is set based on the first ZQ calibration code.

According to embodiments, the second set of calibration units includes multiple calibration units (e.g., calibration units C and D) and the third set of calibration units includes multiple calibration units (e.g., calibration units E and F), where each calibration unit includes an array of transistor sets. The respective array of transistor sets of the respective calibration units of the second set of calibration units and the third set of calibration units are used to generate a second ZQ calibration code used to calibrate the pull-down circuits 414 of the output buffer 411 of the I/O circuit 410.

According to embodiments, the array of transistor sets of each calibration unit (e.g., calibration units C, D, E, and F) include a first transistor set of N transistors (e.g., N=8), a second transistor set of N/2 transistors, a third set of N/4 transistors, a fourth transistor set of N/8 transistors, and a fifth set of N/16 transistors (e.g., a one-half transistor, where N=8). According to the embodiment shown in FIG. 4, the first ZQ calibration code is copied with a 1-bit shift (e.g., execution of a 1-bit shift operation) to the second set of calibration units since the second set of calibration units have one less transistor set (i.e., the second set of calibration units do not include sixth transistor set). According to the embodiment shown in FIG. 4, the second set of calibration units copies the first ZQ calibration code to calibrate the impedance of the pull-up units 412 of the output buffer 411.

According to the embodiment shown in FIG. 4, the 1-bit shifted copy operation of the first ZQ calibration code is used by the second set of calibration units and the third set of calibration units to generate the second ZQ calibration code. The second ZQ calibration code is provided by the third set of calibration units to calibrate the pull-down units 414 of the output buffer 411, as shown in FIG. 4. According to embodiments, the level of current (e.g., the first current level) that passes from the second set of calibration units to the third set of calibration units is increased (e.g., doubled) as a result of the 1-bit shift operation associated with shifting the selected bits (Bit 1 to Bit 5) corresponding to the second transistor set to the sixth transistor set of first set of calibration units (e.g., calibration unit A and calibration unit B of FIG. 4) when copying the first ZQ calibration code to the second set of calibration units (e.g., calibration unit B and C of FIG. 4).

According to embodiments, the ZQ calibration circuit 400 includes a voltage comparator 420 which, in response to a ZQ calibration command, performs a comparison of a first voltage associated with the ZQ calibration circuit 400 (e.g., Vzq1 corresponding to the first set of calibration units used for calibrating the pull-up units 412 of the output buffer 411) or a second voltage associated with the ZQ calibration circuit 400 (e.g., Vzq2 corresponding to the second and third sets of calibration units used to calibrate the pull-down units 414 of the output buffer 411) and a reference voltage (Vref). According to embodiments, the first set of calibration units associated with generating the first ZQ calibration code used to calibrate the pull-up units 412 are tuned until Vzq1 reaches Vref, at which time calibration of the pull-down units 414 is executed using Vzq2 corresponding to the second and third sets of calibration units, as described above.

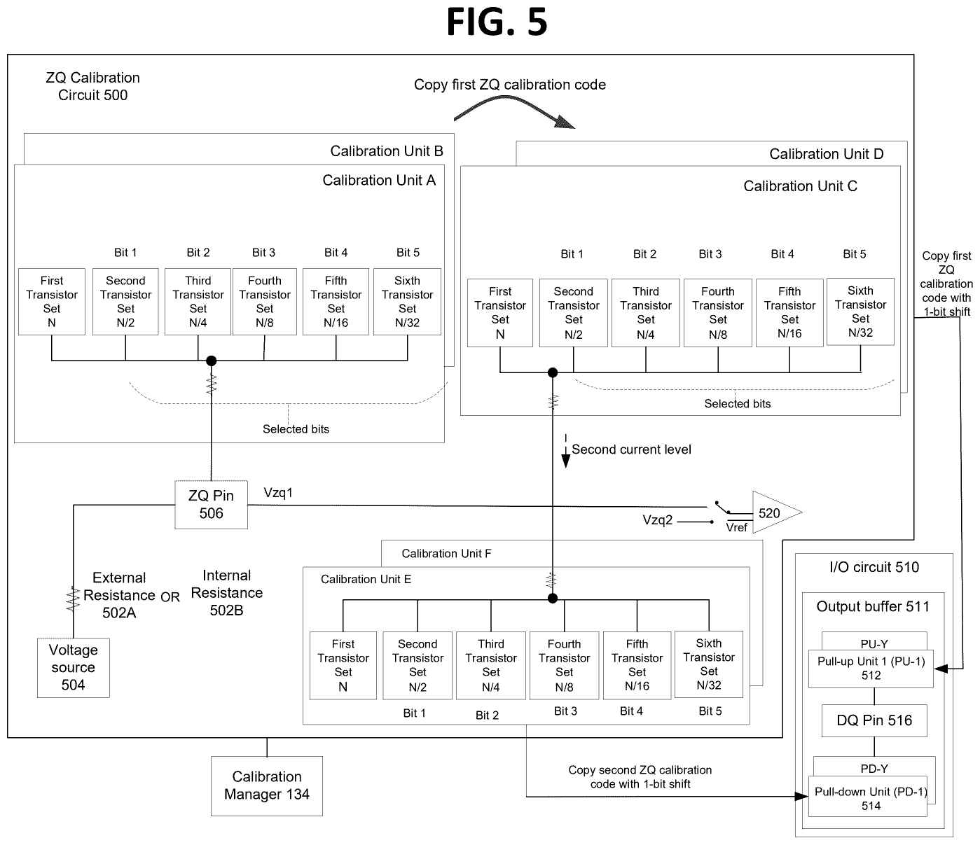

FIG. 5 illustrates an example impedance (ZQ) calibration control circuit 500 of a memory sub-system, according to an embodiment of the present disclosure. FIG. 5 illustrates a calibration manager 134 to control operation of the ZQ calibration control circuit 500 configured to perform ZQ calibration of a memory device of a memory sub-system. According to an embodiment, as shown in FIG. 5, the calibration manager 134 sends one or more commands to the ZQ calibration circuit 500 to cause the calibration units (e.g., calibration unit A, calibration unit B, calibration unit C, calibration unit D, calibration unit E, and calibration unit F) to perform ZQ calibration to generate calibration codes (e.g., a sequence of binary bits, such as 00000, 00001, 10000, 11000, etc.) to be provided (i.e., copied) to an output buffer 511 (e.g., a data (DQ) output buffer) of an input/output (I/O) circuit 510 of the memory sub-system. In an embodiment, the calibration code represents calibration parameters that are supplied to respective pull-up units and pull-down units of the output buffer 511 of the I/O circuit 510 to set the programmable termination components (i.e., the pull-up units and pull-down units) to the desired impedance for the output buffer 511 of the I/O circuit 510.

According to embodiments, the output buffer 511 of the memory sub-system includes data (DQ) circuitry to receive data transactions from a memory sub-system controller via a DQ bus coupled to one or more DQ pins representing a set of DQ lines. According to embodiments, the output buffer 511 includes a data input terminal DQ 516 and a set of pull-up units 512 (e.g., PU-1 to PU-Y and a set of pull-down units 514 (e.g., PD-1 to PD-Y). In an embodiment, output nodes of the pull-up units 512 and pull-down units 514 are coupled in common to a corresponding data input/output terminal via resistors. In an embodiment, the pull-up units 512 (e.g., pull-up unit 1 to pull-up unit Y, where Y equals 8) have the same circuit configuration and are collectively referred to as pull-up units 512. Similarly, the pull-down units (e.g., pull-down unit 1 to pull-down unit Y, where Y equals 8) have the same circuit configuration and are collectively referred to as pull-down units 514.

According to embodiments, corresponding pull-up units and the pull-down units are paired. According to embodiments, the impedance of each of the activated pull-up units 512 is specified by the first ZQ calibration code and the impedance of each of the activated pull-down units 514 is specified by the second ZQ calibration code.

In the embodiment shown in FIG. 5, each calibration unit has a resistance rating or level (e.g., a 300 ohm unit, a 600 ohm unit, etc.). In an embodiment of the ZQ calibration circuit 400 shown in FIG. 5, an external resistance 502A is provided having a resistance value (e.g., 300 ohms) generated by a voltage source 504 supplying a voltage (e.g., VSS) to generate a reference impedance that is coupled to a calibration terminal or pin (ZQ pin 506). According to embodiments, the calibration manager 134 is configured to perform ZQ calibration using the external resistance 502A to establish a match between the resistance or impedance levels of the ZQ pin and the DQ pin of the output buffer 511.

In another embodiment of the ZQ calibration circuit 500 shown in FIG. 4, an internal resistance 502B (e.g., on memory die resistance) is provided having a resistance value (e.g., 300 ohms) generated by a voltage source 504 supplying a voltage (e.g., VSS) to generate a reference impedance that is coupled to a calibration terminal or pin (ZQ pin 506). According to embodiments, the calibration manager 134 is configured to perform ZQ calibration using the internal resistance 502B to establish a match between the resistance or impedance levels of the ZQ pin and the DQ pin of the output buffer 511.

In an embodiment, a first set of calibration units (e.g., calibration unit A and calibration unit B) are configured to generate a first ZQ calibration code that is used to calibrate a pull-up unit 512 of the output buffer 511 of the memory sub-system. In an embodiment, a second set of calibration units (e.g., calibration unit C, calibration unit D) and a third set of calibration units (e.g., calibration unit E and calibration unit F) are configured to generate a second ZQ calibration code to calibrate respective pull-down units 514 of the output buffer 511 of the I/O circuit 510.

According to the embodiment of FIG. 5, each calibration unit includes an array of transistor sets, where each transistor set includes one or more transistors (e.g., one transistor, two transistors, four transistors, eight transistors, etc.) or a portion of a transistor (e.g., a one-half transistor, a one-quarter transistor, etc.) that are used to generate respective bits of a corresponding calibration code.

According to the embodiment of FIG. 5, the first set of calibration units includes calibration unit A and calibration unit B, where each calibration unit includes an array of transistor sets (e.g., first transistor set, second transistor set . . . and sixth transistor set). According to the embodiment of FIG. 5, the first transistor set of calibration unit A and calibration unit B includes N number of transistors. In the example shown in FIG. 5, N equals 8. In the example shown in FIG. 5, the second transistor set of calibration unit A and calibration unit B includes N/2 number of transistors (e.g., 4 transistors). In the example shown in FIG. 5, the third transistor set of calibration unit A and calibration unit B includes N/4 number of transistors (e.g., 2 transistors). In the example shown in FIG. 5, the fourth transistor set of calibration unit A and calibration unit B includes N/8 number of transistors (e.g., 1 transistor). In the example shown in FIG. 5, the fifth transistor set of calibration unit A and calibration unit B includes N/16 number of transistors (e.g., a one-half transistor). In the example shown in FIG. 5, the sixth transistor set of calibration unit A and calibration unit B includes N/32 number of transistors (e.g., a one-quarter transistor).

In an embodiment, the calibration manager 134 sends a calibration command to the first set of calibration units (e.g., using ZQ pin 406 associated with the memory device) to cause the first set of calibration units to generate the first ZQ calibration code (e.g., a five-bit binary sequence). In the embodiment shown in FIG. 5, a first bit (Bit 1) of the first ZQ calibration code is generated by the respective second transistor sets of calibration unit A and calibration unit B. In the embodiment shown in FIG. 5, a second bit (Bit 2) of the first ZQ calibration code is generated by the respective third transistor sets of calibration unit A and calibration unit B. In the embodiment shown in FIG. 5, a third bit (Bit 3) of the first ZQ calibration code is generated by the respective fourth transistor sets of calibration unit A and calibration unit B. In the embodiment shown in FIG. 5, a fourth bit (Bit 4) of the first ZQ calibration code is generated by the respective fifth transistor sets of calibration unit A and calibration unit B. In the embodiment shown in FIG. 5, a fifth bit (Bit 5) of the first ZQ calibration code is generated by the respective sixth transistor sets of calibration unit A and calibration unit B.

Advantageously, the third bit (Bit 3) is generated based on both a first single transistor of the fourth transistor set of calibration unit A and a second single transistor of the fourth transistor set of calibration unit B. Accordingly, the third bit value is determined based on the two transistors (one from each of the respective fourth transistor sets of calibration unit A and calibration unit B, respectively), which provides for robust and accurate coding since variations present with respect to the two individual transistors are offset by generating the bit value based on an average of the two transistors. This helps to reduce the effects of transistor variation that can lead to inaccurate coding when a bit value is based on a single transistor.

In the embodiment shown in FIG. 5, the first ZQ calibration code (e.g., Bit 1 through Bit 5) generated by the first set of calibration units (calibration unit A and calibration unit B) is copied to the second set of calibration units (e.g., calibration unit C and calibration unit D), which in turn copies or provides to the I/O circuit 510 for use in calibrating a respective pull-up unit 512 of the set of pull-up units of the output buffer 511 of the I/O circuit 510. According to embodiments, the impedance of the respective pull-up unit 512 is set based on the first ZQ calibration code.

According to the embodiment shown in FIG. 5, the second set of calibration units (e.g., calibration units C and D) and the third set of calibration units (e.g., calibration units E and F), like the first set of calibration units, are “extended” to include the sixth transistor set (e.g., the set of N/32 transistors (e.g., a one-quarter transistor). Accordingly, like the first set of calibration circuits, the second set of calibration units and the third set of calibration units each include a first transistor set of N transistors (e.g., N=8), a second transistor set of N/2 transistors, a third set of N/4 transistors, a fourth transistor set of N/8 transistors, a fifth set of N/16 transistors (e.g., a one-half transistor, where N=8), and a sixth set of N/32 transistors (e.g., a one-quarter transistor, where N=8). In this embodiment, since both the first set of calibration units and the second set of calibration units are extended to include six transistor sets, the first ZQ calibration code can be copied from the first set of calibration units to the second set of calibration units without the 1-bit shift operation, as compared to the embodiment of FIG. 4.

According to the embodiment shown in FIG. 5, the first ZQ calibration code is copied with a 1-bit shift from the second set of calibration units to the pull-up units 512 since the pull-up units 512 have one less transistor set (i.e., the pull-up units 512 do not include the sixth transistor set). According to the embodiment shown in FIG. 5, the second set of calibration units copies the first ZQ calibration code (with the 1-bit shift operation) to calibrate the impedance of the pull-up units 512 of the output buffer 511.

According to embodiments, the second set of calibration units includes multiple calibration units (e.g., calibration units C and D) and the third set of calibration units includes multiple calibration units (e.g., calibration units E and F), where each calibration unit includes the extended array of transistor sets (e.g., a first transistor set, a second transistor set . . . and a sixth transistor set). The respective array of transistor sets of the respective calibration units of the second set of calibration units and the third set of calibration units are used to generate a second ZQ calibration code used to calibrate the pull-down circuits 514 of the output buffer 511 of the I/O circuit 510.

According to the embodiment shown in FIG. 5, the second ZQ calibration code is copied from the “extended” third set of calibration units to the pull-down units 514 using a 1-bit shift operation since the pull-down units 514 include one less transistor set. According to the embodiment shown in FIG. 5, the level of current (e.g., the second current level) that passes from the second set of calibration units to the third set of calibration units is decreased, as compared to the first current level of the embodiment of FIG. 4, since the copying of the code from the second set of calibration units to the third set of calibration units does not require bit shifting (i.e., less current is consumed as compared to the embodiment shown in FIG. 4).

According to embodiments, the ZQ calibration circuit 500 includes a voltage comparator 520 which, in response to a ZQ calibration command, performs a comparison of a first voltage associated with the ZQ calibration circuit 500 (e.g., Vzq1 corresponding to the first set of calibration units used for calibrating the pull-up units 512 of the output buffer 511) or a second voltage associated with the ZQ calibration circuit 500 (e.g., Vzq2 corresponding to the second and third sets of calibration units used to calibrate the pull-down units 514 of the output buffer 511) and a reference voltage (Vref). According to embodiments, the first set of calibration units associated with generating the first ZQ calibration code used to calibrate the pull-up units 512 are tuned until Vzq1 reaches Vref, at which time calibration of the pull-down units 514 is executed using Vzq2 corresponding to the second and third sets of calibration units, as described above.

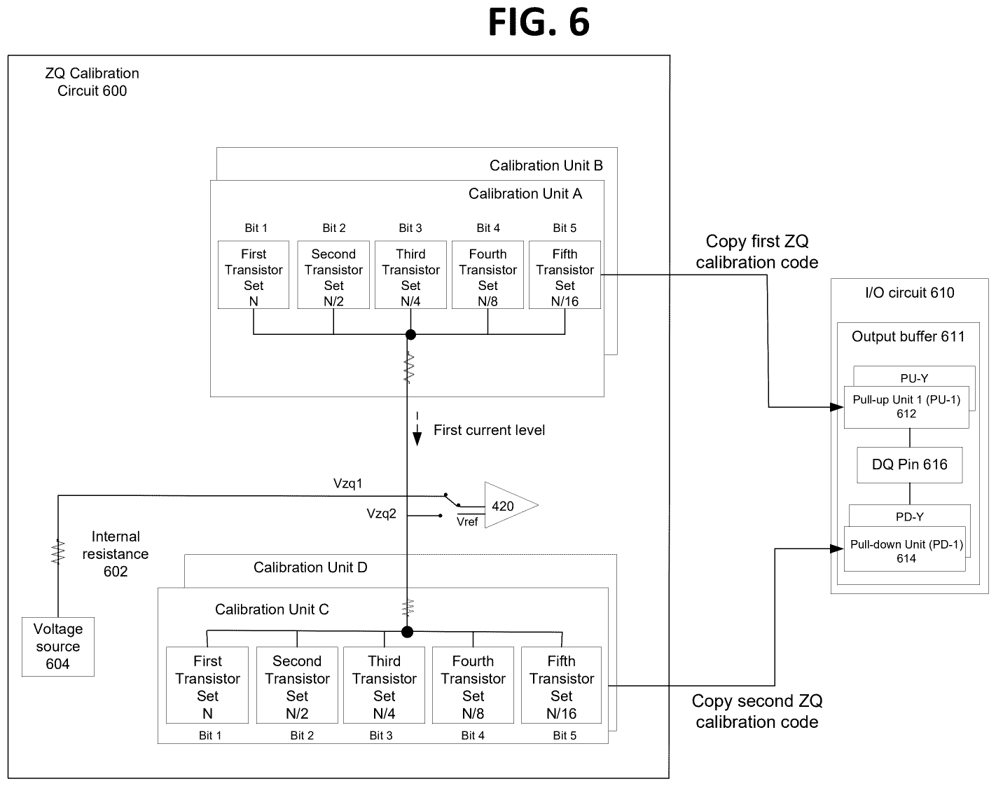

FIG. 6 illustrates an example impedance (ZQ) calibration control circuit 600 of a memory sub-system, according to an embodiment of the present disclosure. FIG. 6 illustrates a calibration manager 134 to control operation of the ZQ calibration control circuit 600 configured to perform ZQ calibration of a memory device of a memory sub-system. According to an embodiment, as shown in FIG. 6, the calibration manager 134 sends one or more commands to the ZQ calibration circuit 600 to cause the calibration units (e.g., calibration unit A, calibration unit B, calibration unit C, and calibration unit D) to perform ZQ calibration to generate calibration codes (e.g., a sequence of binary bits, such as 00000, 00001, 10000, 11000, etc.) to be provided (i.e., copied) to an output buffer 611 (e.g., a data (DQ) output buffer) of an input/output (I/O) circuit 610 of the memory sub-system. In an embodiment, the calibration code represents calibration parameters that are supplied to respective pull-up units and pull-down units of the output buffer 611 of the I/O circuit 610 to set the programmable termination components (i.e., the pull-up units and pull-down units) to the desired impedance for the output buffer 611 of the I/O circuit 610.

According to embodiments, the output buffer 611 of the memory sub-system includes data (DQ) circuitry to receive data transactions from a memory sub-system controller via a DQ bus coupled to one or more DQ pins representing a set of DQ lines. According to embodiments, the output buffer 611 includes a data input terminal DQ 616 and a set of pull-up units 612 (e.g., PU-1 to PU-Y and a set of pull-down units 614 (e.g., PD-1 to PD-Y). In an embodiment, output nodes of the pull-up units 612 and pull-down units 614 are coupled in common to a corresponding data input/output terminal via resistors. In an embodiment, the pull-up units 612 (e.g., pull-up unit 1 to pull-up unit Y, where Y equals 8) have the same circuit configuration and are collectively referred to as pull-up units 612. Similarly, the pull-down units (e.g., pull-down unit 1 to pull-down unit Y, where Y equals 8) have the same circuit configuration and are collectively referred to as pull-down units 614.

According to embodiments, corresponding pull-up units and the pull-down units are paired. According to embodiments, the impedance of each of the activated pull-up units 612 is specified by the first ZQ calibration code and the impedance of each of the activated pull-down units 614 is specified by the second ZQ calibration code.

In the embodiment shown in FIG. 6, each calibration unit has a resistance rating or level (e.g., a 300 ohm unit, a 600 ohm unit, etc.). In an embodiment of the ZQ calibration circuit 600 shown in FIG. 6, an internal resistance 602 is provided having a resistance value (e.g., 300 ohms) generated by a voltage source 604 supplying a voltage (e.g., VSS) to generate a reference impedance. According to embodiments, the calibration manager 134 is configured to perform ZQ calibration using the internal resistance 602 to establish a match between the resistance or impedance levels of the ZQ calibration circuit 600 and the DQ pin of the output buffer 611.

In an embodiment, a first set of calibration units (e.g., calibration unit A and calibration unit B) are configured to generate a first ZQ calibration code that is used to calibrate a pull-up unit 612 of the output buffer 611 of the memory sub-system. In an embodiment, a second set of one or more calibration units (e.g., calibration unit C, calibration unit D) are configured to generate a second ZQ calibration code to calibrate respective pull-down units 614 of the output buffer 611 of the I/O circuit 610.

According to the embodiment of FIG. 6, each calibration unit includes an array of transistor sets, where each transistor set includes one or more transistors (e.g., one transistor, two transistors, four transistors, eight transistors, etc.) or a portion of a transistor (e.g., a one-half transistor, a one-quarter transistor, etc.) that are used to generate respective bits of a corresponding calibration code.

According to the embodiment of FIG. 6, the first set of calibration units includes calibration unit A and calibration unit B, where each calibration unit includes an array of transistor sets (e.g., first transistor set, second transistor set . . . fifth transistor set). According to the embodiment of FIG. 6, the first transistor set of calibration unit A and calibration unit B includes N number of transistors. In the example shown in FIG. 6, N equals 8. In the example shown in FIG. 6, the second transistor set of calibration unit A and calibration unit B includes N/2 number of transistors (e.g., 4 transistors). In the example shown in FIG. 6, the third transistor set of calibration unit A and calibration unit B includes N/4 number of transistors (e.g., 2 transistors). In the example shown in FIG. 6, the fourth transistor set of calibration unit A and calibration unit B includes N/8 number of transistors (e.g., 1 transistor). In the example shown in FIG. 6, the fifth transistor set of calibration unit A and calibration unit B includes N/16 number of transistors (e.g., a one-half transistor).

In an embodiment, the calibration manager 134 sends a calibration command to the first set of calibration units (e.g., calibration unit A and calibration unit B) to cause the first set of calibration units to generate the first ZQ calibration code (e.g., a five-bit binary sequence). In the embodiment shown in FIG. 6, a first bit (Bit 1) of the first ZQ calibration code is generated by the respective first transistor sets of calibration unit A and calibration unit B. In the embodiment shown in FIG. 6, a second bit (Bit 2) of the first ZQ calibration code is generated by the respective second transistor sets of calibration unit A and calibration unit B. In the embodiment shown in FIG. 6, a third bit (Bit 3) of the first ZQ calibration code is generated by the respective third transistor sets of calibration unit A and calibration unit B. In the embodiment shown in FIG. 6, a fourth bit (Bit 4) of the first ZQ calibration code is generated by the respective fourth transistor sets of calibration unit A and calibration unit B. In the embodiment shown in FIG. 6, a fifth bit (Bit 5) of the first ZQ calibration code is generated by the respective fifth transistor sets of calibration unit A and calibration unit B.

Advantageously, the fourth bit (Bit 4) is generated based on both a first single transistor of the fourth transistor set of calibration unit A and a second single transistor of the fourth transistor set of calibration unit B. Accordingly, the fourth bit value is determined based on the two transistors (one from each of the respective fourth transistor sets of calibration unit A and calibration unit B, respectively), which provides for robust and accurate coding since variations present with respect to the two individual transistors are offset by generating the bit value based on an average of the two transistors. This helps to reduce the effects of transistor variation that can lead to inaccurate coding when a bit value is based on a single transistor.

In the embodiment shown in FIG. 6, the first ZQ calibration code (e.g., Bit 1 through Bit 5) generated by the first set of calibration units (calibration unit A and calibration unit B) is copied to the pull-up units 612 of the output buffer 611 of the I/O circuit 610. Accordingly, the first ZQ calibration code is used to calibrate a respective pull-up unit 412 of the set of pull-up units. According to embodiments, the impedance of the respective pull-up unit 612 is set based on the first ZQ calibration code generated by the first set of calibration units.

According to embodiments, the second set of calibration units includes multiple calibration units (e.g., calibration units C and D), where each calibration unit includes an array of transistor sets. The respective array of transistor sets of the respective calibration units of the second set of calibration units are used to generate a second ZQ calibration code used to calibrate the pull-down circuits 614 of the output buffer 611 of the I/O circuit 610.

According to embodiments, the array of transistor sets of each calibration unit (e.g., calibration units C and D) include a first transistor set of N transistors (e.g., N=8), a second transistor set of N/2 transistors, a third set of N/4 transistors, a fourth transistor set of N/8 transistors, and a fifth set of N/16 transistors (e.g., a one-half transistor, where N=8). According to the embodiment shown in FIG. 6, the second set of calibration units generates the second ZQ calibration code using the array of transistor sets of calibration units C and D and copies the second ZQ calibration code to the pull-down units 614 of the output buffer 611 to calibrate the impedance of the pull-down units 614.

According to embodiments, the ZQ calibration circuit 600 includes a voltage comparator 620 which, in response to a ZQ calibration command, performs a comparison of a first voltage associated with the ZQ calibration circuit 600 (e.g., Vzq1 corresponding to the first set of calibration units used for calibrating the pull-up units 612 of the output buffer 611) or a second voltage associated with the ZQ calibration circuit 600 (e.g., Vzq2 corresponding to the second and third sets of calibration units used to calibrate the pull-down units 614 of the output buffer 611) and a reference voltage (Vref). According to embodiments, the first set of calibration units associated with generating the first ZQ calibration code used to calibrate the pull-up units 612 are tuned until Vzq1 reaches Vref, at which time calibration of the pull-down units 614 is executed using Vzq2 corresponding to the second and third sets of calibration units, as described above.

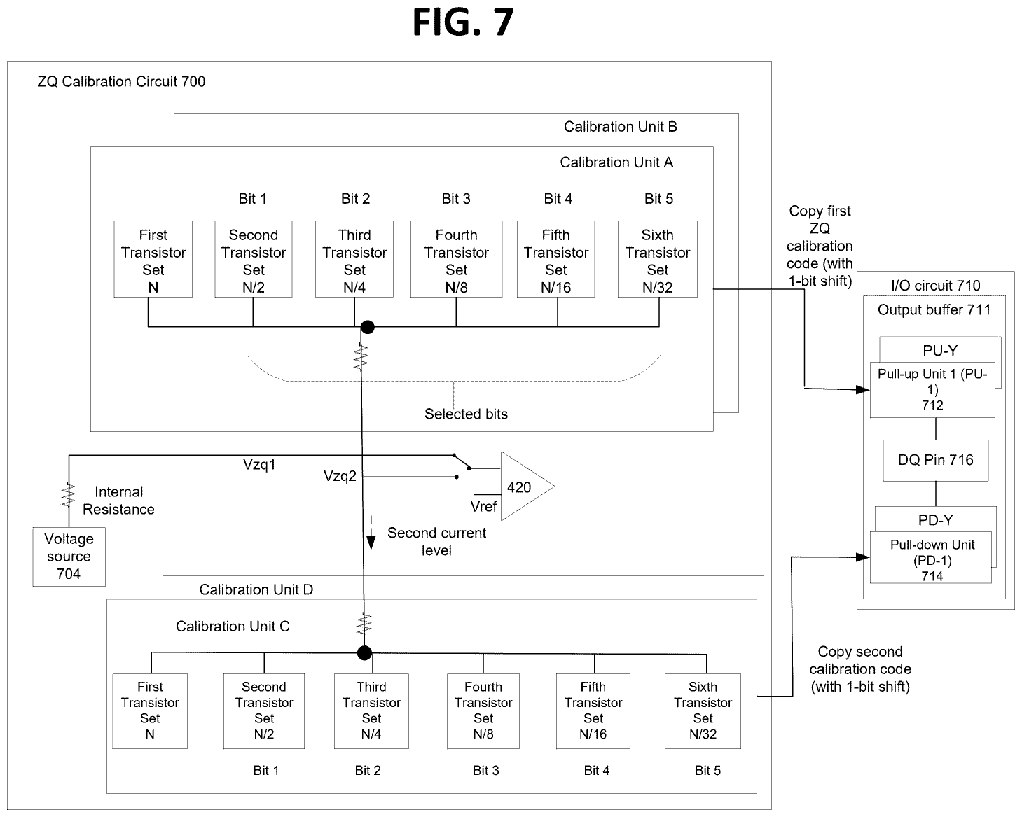

FIG. 7 illustrates an example impedance (ZQ) calibration control circuit 700 of a memory sub-system, according to an embodiment of the present disclosure. FIG. 7 illustrates a calibration manager 134 to control operation of the ZQ calibration control circuit 700 configured to perform ZQ calibration of a memory device of a memory sub-system. According to an embodiment, as shown in FIG. 7, the calibration manager 134 sends one or more commands to the ZQ calibration circuit 700 to cause the calibration units (e.g., calibration unit A, calibration unit B, calibration unit C, and calibration unit D) to perform ZQ calibration to generate calibration codes (e.g., a sequence of binary bits, such as 00000, 00001, 10000, 11000, etc.) to be provided (i.e., copied) to an output buffer 711 (e.g., a data (DQ) output buffer) of an input/output (I/O) circuit 710 of the memory sub-system. In an embodiment, the calibration code represents calibration parameters that are supplied to respective pull-up units and pull-down units of the output buffer 711 of the I/O circuit 710 to set the programmable termination components (i.e., the pull-up units and pull-down units) to the desired impedance for the output buffer 711 of the I/O circuit 710.

According to embodiments, the output buffer 711 of the memory sub-system includes data (DQ) circuitry to receive data transactions from a memory sub-system controller via a DQ bus coupled to one or more DQ pins representing a set of DQ lines. According to embodiments, the output buffer 611 includes a data input terminal DQ 716 and a set of pull-up units 612 (e.g., PU-1 to PU-Y and a set of pull-down units 714 (e.g., PD-1 to PD-Y). In an embodiment, output nodes of the pull-up units 712 and pull-down units 714 are coupled in common to a corresponding data input/output terminal via resistors. In an embodiment, the pull-up units 712 (e.g., pull-up unit 1 to pull-up unit Y, where Y equals 8) have the same circuit configuration and are collectively referred to as pull-up units 712. Similarly, the pull-down units (e.g., pull-down unit 1 to pull-down unit Y, where Y equals 8) have the same circuit configuration and are collectively referred to as pull-down units 714.

According to embodiments, corresponding pull-up units and the pull-down units are paired. According to embodiments, the impedance of each of the activated pull-up units 712 is specified by the first ZQ calibration code and the impedance of each of the activated pull-down units 714 is specified by the second ZQ calibration code.

In the embodiment shown in FIG. 7, each calibration unit has a resistance rating or level (e.g., a 300 ohm unit, a 600 ohm unit, etc.). In an embodiment of the ZQ calibration circuit 600 shown in FIG. 7, an internal resistance 702 is provided having a resistance value (e.g., 300 ohms) generated by a voltage source 704 supplying a voltage (e.g., VSS) to generate a reference impedance. According to embodiments, the calibration manager 134 is configured to perform ZQ calibration using the internal resistance 702 to establish a match between the resistance or impedance levels of the ZQ calibration circuit 700 and the DQ pin of the output buffer 711.

In an embodiment, a first set of calibration units (e.g., calibration unit A and calibration unit B) are configured to generate a first ZQ calibration code that is used to calibrate a pull-up unit 712 of the output buffer 711 of the memory sub-system. In an embodiment, a second set of one or more calibration units (e.g., calibration unit C, calibration unit D) are configured to generate a second ZQ calibration code to calibrate respective pull-down units 714 of the output buffer 711 of the I/O circuit 710.

According to the embodiment of FIG. 7, each calibration unit includes an array of transistor sets, where each transistor set includes one or more transistors (e.g., one transistor, two transistors, four transistors, eight transistors, etc.) or a portion of a transistor (e.g., a one-half transistor, a one-quarter transistor, etc.) that are used to generate respective bits of a corresponding calibration code.

According to the embodiment of FIG. 7, the first set of calibration units includes calibration unit A and calibration unit B, where each calibration unit includes an “extended” array of transistor sets (e.g., first transistor set, second transistor set . . . and sixth transistor set). According to the embodiment of FIG. 7, the first transistor set of calibration unit A and calibration unit B includes N number of transistors. In the example shown in FIG. 7, N equals 8. In the example shown in FIG. 7, the second transistor set of calibration unit A and calibration unit B includes N/2 number of transistors (e.g., 4 transistors). In the example shown in FIG. 7, the third transistor set of calibration unit A and calibration unit B includes N/4 number of transistors (e.g., 2 transistors). In the example shown in FIG. 7, the fourth transistor set of calibration unit A and calibration unit B includes N/8 number of transistors (e.g., 1 transistor). In the example shown in FIG. 7, the fifth transistor set of calibration unit A and calibration unit B includes N/16 number of transistors (e.g., a one-half transistor). In the example shown in FIG. 7, the sixth transistor set of calibration unit A and calibration unit B includes N/32 number of transistors (e.g., a one-quarter transistor).

In an embodiment, the calibration manager 134 sends a calibration command to the first set of calibration units (e.g., calibration unit A and calibration unit B) to cause the first set of calibration units to generate the first ZQ calibration code (e.g., a five-bit binary sequence). In the embodiment shown in FIG. 7, a first bit (Bit 1) of the first ZQ calibration code is generated by the respective second transistor sets of calibration unit A and calibration unit B. In the embodiment shown in FIG. 7, a second bit (Bit 2) of the first ZQ calibration code is generated by the respective third transistor sets of calibration unit A and calibration unit B. In the embodiment shown in FIG. 6, a third bit (Bit 3) of the first ZQ calibration code is generated by the respective fourth transistor sets of calibration unit A and calibration unit B. In the embodiment shown in FIG. 7, a fourth bit (Bit 4) of the first ZQ calibration code is generated by the respective fifth transistor sets of calibration unit A and calibration unit B. In the embodiment shown in FIG. 7, a fifth bit (Bit 5) of the first ZQ calibration code is generated by the respective sixth transistor sets of calibration unit A and calibration unit B.

Advantageously, the third bit (Bit 3) is generated based on both a first single transistor of the fourth transistor set of calibration unit A and a second single transistor of the fourth transistor set of calibration unit B. Accordingly, the third bit value is determined based on the two transistors (one from each of the respective fourth transistor sets of calibration unit A and calibration unit B, respectively), which provides for robust and accurate coding since variations present with respect to the two individual transistors are offset by generating the bit value based on an average of the two transistors. This helps to reduce the effects of transistor variation that can lead to inaccurate coding when a bit value is based on a single transistor.

According to the embodiment shown in FIG. 7, the first ZQ calibration code is copied with a 1-bit shift from the second set of calibration units to the pull-up units 712 since the pull-up units 712 have one less transistor set (i.e., the pull-up units 712 do not include the sixth transistor set). According to the embodiment shown in FIG. 7, the second set of calibration units copies the first ZQ calibration code (with the 1-bit shift operation) to calibrate the impedance of the pull-up units 712 of the output buffer 711.

According to embodiments, the second set of calibration units includes multiple calibration units (e.g., calibration units C and D), where each calibration unit includes the extended array of transistor sets (e.g., a first transistor set, a second transistor set . . . and a sixth transistor set). The respective array of transistor sets of the respective calibration units of the second set of calibration units and the third set of calibration units are used to generate a second ZQ calibration code used to calibrate the pull-down circuits 514 of the output buffer 511 of the I/O circuit 510.

According to the embodiment shown in FIG. 7, the second ZQ calibration code is copied from the “extended” third set of calibration units to the pull-down units 714 using a 1-bit shift since the pull-down units 714 include one less transistor set. According to the embodiment shown in FIG. 7, the level of current (e.g., the second current level) that passes from the first set of calibration units to the second set of calibration units is decreased, as compared to the first current level of the embodiment of FIG. 7, since the copying of the code from the first set of calibration units to the second set of calibration units does not require a bit shifting operation (i.e., less current is consumed as compared to the embodiment shown in FIG. 6).

According to embodiments, the ZQ calibration circuit 700 includes a voltage comparator 720 which, in response to a ZQ calibration command, performs a comparison of a first voltage associated with the ZQ calibration circuit 700 (e.g., Vzq1 corresponding to the first set of calibration units used for calibrating the pull-up units 712 of the output buffer 711) or a second voltage associated with the ZQ calibration circuit 700 (e.g., Vzq2 corresponding to the second and third sets of calibration units used to calibrate the pull-down units 714 of the output buffer 711) and a reference voltage (Vref). According to embodiments, the first set of calibration units associated with generating the first ZQ calibration code used to calibrate the pull-up units 712 are tuned until Vzq1 reaches Vref, at which time calibration of the pull-down units 714 is executed using Vzq2 corresponding to the second and third sets of calibration units, as described above.

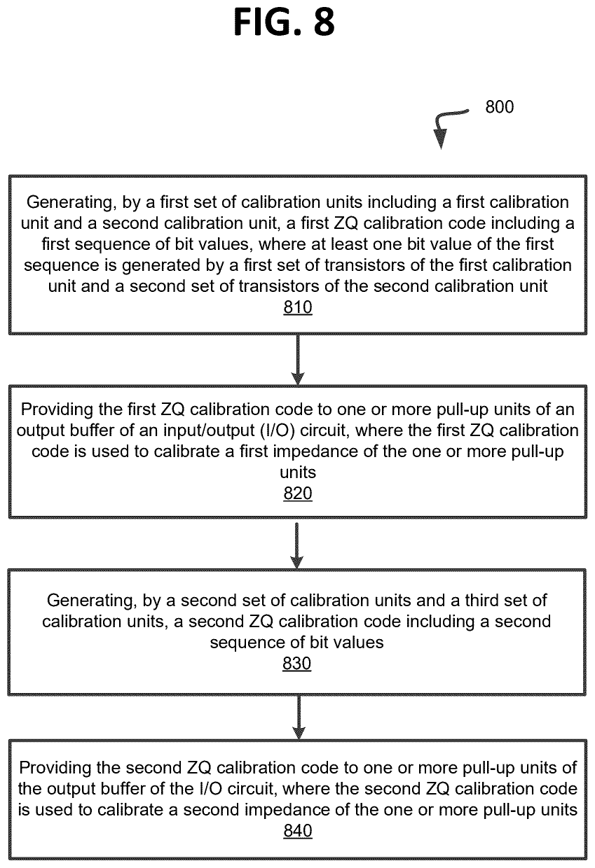

FIG. 8 is a flow diagram of an example method 800 of calibrating pull-up units and pull-down units of an output buffer of an I/O circuit of a memory device in a memory sub-system, in accordance with one or more embodiments of the present disclosure. The method 800 is described with reference to FIGS. 4-7. The method 800 can be performed by processing logic that can include hardware (e.g., processing device, circuitry, dedicated logic, programmable logic, microcode, hardware of a device, integrated circuit, etc.), software (e.g., instructions run or executed on a processing device), or a combination thereof. In some embodiments, the method 800 is performed by calibration manager 134 of FIG. 1A-FIG. 7. Although shown in a particular sequence or order, unless otherwise specified, the order of the processes can be modified. Thus, the illustrated embodiments should be understood only as examples, and the illustrated processes can be performed in a different order, and some processes can be performed in parallel. Additionally, one or more processes can be omitted in various embodiments. Thus, not all processes are required in every embodiment. Other process flows are possible.

At operation 810, a first sequence of bit values is generated. For example, in response to a command received from control logic (e.g., calibration manager 134), a first set of calibration units include a first calibration unit (e.g., calibration unit A shown in FIGS. 4-7) and a second calibration unit (e.g., calibration unit B shown in FIGS. 4-7) can generate a first ZQ calibration code including a first sequence of bit values, where at least one bit value of the first sequence is generated by a first set of transistors of the first calibration unit and a second set of transistors of the second calibration unit. According to an embodiment, the respective bit values of the first sequence of bit values are each generated by corresponding transistor sets of the first calibration unit and the second calibration unit. In an embodiment, each bit value is generated by averaging the bit values generated by the corresponding transistor sets of the calibration units of the set of calibration units.

At operation 820, the first sequence of bit values is provided. For example, the first ZQ calibration code is provided to one or more pull-up units of an output buffer of an I/O circuit, where the first ZQ calibration code is used to calibrate a first impedance of the one or more pull-up units. In an embodiment, the first ZQ calibration code is copied, using a 1-bit shifting operation from the first set of calibration units to a second set of calibration units, which in turn copies the 1-bit shifted first ZQ calibration code to the one or more pull-up units (e.g., as described in detail with reference to FIG. 4). In an embodiment, the first ZQ calibration code is copied by the first set of calibration units to the one or more pull-up units (e.g., as described in detail with reference to FIG. 6).

At operation 830, a second sequence of bit values is generated. For example, a second set of calibration units (e.g., calibration units C and D shown in FIGS. 4 and 5) and a third set of calibration units (e.g., calibration units E and F shown in FIGS. 4 and 5) can generate a second ZQ calibration code including a second sequence of bit values.

At operation 840, the second sequence is provided. For example, the second ZQ calibration code is provided to one or more pull-down units of the output buffer of the I/O circuit, where the second ZQ calibration code is used to calibrate a second impedance of the one or more pull-down units. In an embodiment, the second ZQ calibration code is copied from the third set of calibration units to the one or more pull-down units of the output buffer (as described in detail above with reference to FIGS. 4-5). In an embodiment, the second ZQ calibration code is copied to the one or more pull-down units using a 1-bit shift operation (as described above with reference to FIG. 5). In an embodiment, the second ZQ calibration code is copied from the second set of calibration units to the pull-down units of the output buffer (as described above with reference to FIGS. 6 and 7).

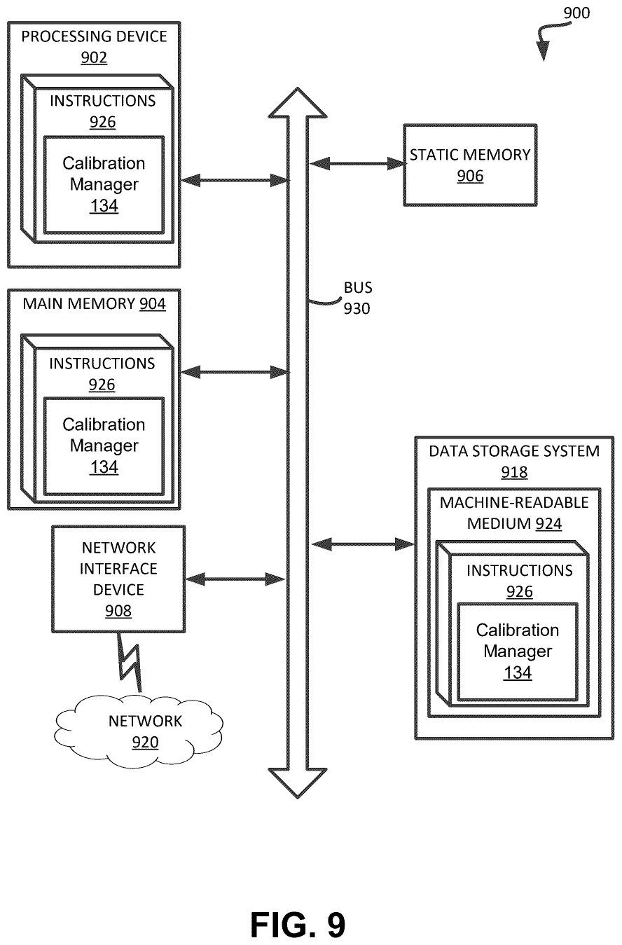

FIG. 9 illustrates an example machine of a computer system 900 within which a set of instructions, for causing the machine to perform any one or more of the methodologies discussed herein, can be executed. In some embodiments, the computer system 900 can correspond to a host system (e.g., the host system 120 of FIG. 1A) that includes, is coupled to, or utilizes a memory sub-system (e.g., the memory sub-system 110 of FIG. 1A) or can be used to perform the operations of a controller (e.g., to execute an operating system to perform operations corresponding to calibration manager 134 of FIGS. 1A and 1B). In alternative embodiments, the machine can be connected (e.g., networked) to other machines in a LAN, an intranet, an extranet, and/or the Internet. The machine can operate in the capacity of a server or a client machine in client-server network environment, as a peer machine in a peer-to-peer (or distributed) network environment, or as a server or a client machine in a cloud computing infrastructure or environment.

The machine can be a personal computer (PC), a tablet PC, a set-top box (STB), a Personal Digital Assistant (PDA), a cellular telephone, a web appliance, a server, a network router, a switch or bridge, or any machine capable of executing a set of instructions (sequential or otherwise) that specify actions to be taken by that machine. Further, while a single machine is illustrated, the term “machine” shall also be taken to include any collection of machines that individually or jointly execute a set (or multiple sets) of instructions to perform any one or more of the methodologies discussed herein.

The example computer system 900 includes a processing device 902, a main memory 904 (e.g., read-only memory (ROM), flash memory, dynamic random access memory (DRAM) such as synchronous DRAM (SDRAM) or Rambus DRAM (RDRAM), etc.), a static memory 906 (e.g., flash memory, static random access memory (SRAM), etc.), and a data storage system 918, which communicate with each other via a bus 930.

Processing device 902 represents one or more general-purpose processing devices such as a microprocessor, a central processing unit, or the like. More particularly, the processing device can be a complex instruction set computing (CISC) microprocessor, reduced instruction set computing (RISC) microprocessor, very long instruction word (VLIW) microprocessor, or a processor implementing other instruction sets, or processors implementing a combination of instruction sets. Processing device 902 can also be one or more special-purpose processing devices such as an application specific integrated circuit (ASIC), a field programmable gate array (FPGA), a digital signal processor (DSP), network processor, or the like. The processing device 902 is configured to execute instructions 926 for performing the operations and steps discussed herein. The computer system 900 can further include a network interface device 908 to communicate over the network 920.

The data storage system 918 can include a machine-readable storage medium 924 (also known as a computer-readable medium, such as a non-transitory computer-readable medium) on which is stored one or more sets of instructions 926 or software embodying any one or more of the methodologies or functions described herein. The instructions 926 can also reside, completely or at least partially, within the main memory 904 and/or within the processing device 902 during execution thereof by the computer system 900, the main memory 904 and the processing device 902 also constituting machine-readable storage media. The machine-readable storage medium 924, data storage system 918, and/or main memory 904 can correspond to the memory sub-system 110 of FIG. 1A.

In one embodiment, the instructions 926 include instructions to implement functionality corresponding to calibration manager 134 of FIGS. 1A and 1B). While the machine-readable storage medium 924 is shown in an example embodiment to be a single medium, the term “machine-readable storage medium” should be taken to include a single medium or multiple media that store the one or more sets of instructions. The term “machine-readable storage medium” shall also be taken to include any medium that is capable of storing or encoding a set of instructions for execution by the machine and that cause the machine to perform any one or more of the methodologies of the present disclosure. The term “machine-readable storage medium” shall accordingly be taken to include, but not be limited to, solid-state memories, optical media, and magnetic media.

Some portions of the preceding detailed descriptions have been presented in terms of algorithms and symbolic representations of operations on data bits within a computer memory. These algorithmic descriptions and representations are the ways used by those skilled in the data processing arts to most effectively convey the substance of their work to others skilled in the art. An algorithm is here, and generally, conceived to be a self-consistent sequence of operations leading to a desired result. The operations are those requiring physical manipulations of physical quantities. Usually, though not necessarily, these quantities take the form of electrical or magnetic signals capable of being stored, combined, compared, and otherwise manipulated. It has proven convenient at times, principally for reasons of common usage, to refer to these signals as bits, values, elements, symbols, characters, terms, numbers, or the like.

It should be borne in mind, however, that all of these and similar terms are to be associated with the appropriate physical quantities and are merely convenient labels applied to these quantities. The present disclosure can refer to the action and processes of a computer system, or similar electronic computing device, that manipulates and transforms data represented as physical (electronic) quantities within the computer system's registers and memories into other data similarly represented as physical quantities within the computer system memories or registers or other such information storage systems.

The present disclosure also relates to an apparatus for performing the operations herein. This apparatus can be specially constructed for the intended purposes, or it can include a general purpose computer selectively activated or reconfigured by a computer program stored in the computer. Such a computer program can be stored in a computer readable storage medium, such as, but not limited to, any type of disk including floppy disks, optical disks, CD-ROMs, and magnetic-optical disks, read-only memories (ROMs), random access memories (RAMs), EPROMs, EEPROMs, magnetic or optical cards, or any type of media suitable for storing electronic instructions, each coupled to a computer system bus.

The algorithms and displays presented herein are not inherently related to any particular computer or other apparatus. Various general purpose systems can be used with programs in accordance with the teachings herein, or it can prove convenient to construct a more specialized apparatus to perform the method. The structure for a variety of these systems will appear as set forth in the description below. In addition, the present disclosure is not described with reference to any particular programming language. It will be appreciated that a variety of programming languages can be used to implement the teachings of the disclosure as described herein.

The present disclosure can be provided as a computer program product, or software, that can include a machine-readable medium having stored thereon instructions, which can be used to program a computer system (or other electronic devices) to perform a process according to the present disclosure. A machine-readable medium includes any mechanism for storing information in a form readable by a machine (e.g., a computer). In some embodiments, a machine-readable (e.g., computer-readable) medium includes a machine (e.g., a computer) readable storage medium such as a read only memory (“ROM”), random access memory (“RAM”), magnetic disk storage media, optical storage media, flash memory components, etc.

In the foregoing specification, embodiments of the disclosure have been described with reference to specific example embodiments thereof. It will be evident that various modifications can be made thereto without departing from the broader spirit and scope of embodiments of the disclosure as set forth in the following claims. The specification and drawings are, accordingly, to be regarded in an illustrative sense rather than a restrictive sense.

What is claimed is:

1. A memory device comprising:
a memory array comprising a plurality of memory cells;
an input/output (I/O) circuit comprising an output buffer coupled to the memory array; and
an impedance (ZQ) calibration circuit coupled to the I/O circuit, the ZQ calibration circuit comprising a first set of calibration units, a second set of calibration units, and a third set of calibration units, the ZQ calibration circuit to perform operations comprising:
generating, by the first set of calibration units comprising a first calibration unit and a second calibration unit, a first ZQ calibration code comprising a first sequence of bit values, wherein at least one bit value of the first sequence is generated by a first transistor set of the first calibration unit and a second transistor set of the second calibration unit;
providing the first ZQ calibration code to one or more pull-up units of the output buffer, wherein the first ZQ calibration code is used to calibrate a first impedance of the one or more pull-up units;
generating, by the second set of calibration units and the third set of calibration units, a second ZQ calibration code comprising a second sequence of bit values; and
providing the second ZQ calibration code to one or more pull-down units of the output buffer, wherein the second ZQ calibration code is used to calibrate a second impedance of the one or more pull-down units.

2. The memory device of claim 1, wherein the first set of calibration units comprises a greater number of transistor sets than the second set of calibration units.

3. The memory device of claim 2, wherein providing, by the first set of calibration units, the first ZQ calibration code comprises a bit shifting operation.

4. The memory device of claim 1, wherein the first set of calibration units, the second set of calibration units, and the third set of calibration units comprise a same number of transistors sets.

5. The memory device of claim 1, wherein the first set of calibration units comprises a greater number of transistors sets than the one or more pull-up units of the output buffer.

6. The memory device of claim 5, wherein providing the first ZQ calibration code to the one or more pull-up units of the output buffer comprises executing a bit shifting operation.

7. The memory device of claim 1, wherein the third set of calibration units comprises a greater number of transistors sets than the one or more pull-down units of the output buffer.

8. The memory device of claim 1, wherein providing the second ZQ calibration code to the one or more pull-down units of the output buffer comprises executing a bit shifting operation.

9. A memory device comprising:
a memory array comprising a plurality of memory cells;
an input/output (I/O) circuit comprising an output buffer coupled to the memory array; and
an impedance (ZQ) calibration circuit coupled to the I/O circuit, the ZQ calibration circuit comprising a first set of calibration units and a second set of calibration units, the ZQ calibration circuit to perform operations comprising:
generating, by the first set of calibration units comprising a first calibration unit and a second calibration unit, a first ZQ calibration code comprising a first sequence of bit values, wherein at least one bit value of the first sequence is generated by a first transistor set of the first calibration unit and a second transistor set of the second calibration unit;
providing, by the first set of calibration units, the first ZQ calibration code to one or more pull-up units of the output buffer, wherein the first ZQ calibration code is used to calibrate a first impedance of the one or more pull-up units;
generating, by a second set of calibration units, a second ZQ calibration code comprising a second sequence of bit values; and
providing, by the second set of calibration units, the second ZQ calibration code to one or more pull-down units of the output buffer, wherein the second ZQ calibration code is used to calibrate a second impedance of the one or more pull-down units.

10. The memory device of claim 9, wherein the first set of calibration units comprises a same number of transistor sets as the one or more pull-up units.

11. The memory device of claim 9, wherein the second set of calibration units comprises a same number of transistor sets as the one or more pull-down units.

12. The memory device of claim 9, wherein the first set of calibration units comprises a greater number of transistors sets than the one or more pull-up units of the output buffer.

13. The memory device of claim 12, wherein providing the first ZQ calibration code to the one or more pull-up units of the output buffer comprises executing a bit shifting operation.

14. The memory device of claim 9, wherein the second set of calibration units comprises a greater number of transistors sets than the one or more pull-down units of the output buffer.

15. The memory device of claim 14, wherein providing the second ZQ calibration code to the one or more pull-down units of the output buffer comprises executing a bit shifting operation.

16. A method comprising:
generating, by a first set of calibration units comprising a first calibration unit and a second calibration unit, a first impedance (ZQ) calibration code comprising a first sequence of bit values, wherein at least one bit value of the first sequence is generated by a first transistor set of the first calibration unit and a second transistor set of the second calibration unit;
providing the first ZQ calibration code to one or more pull-up units of an output buffer of an input/output circuit of a memory device, wherein the first ZQ calibration code is used to calibrate a first impedance of the one or more pull-up units;
generating, by a second set of calibration units and a third set of calibration units, a second ZQ calibration code comprising a second sequence of bit values; and
providing the second ZQ calibration code to one or more pull-down units of the output buffer, wherein the second ZQ calibration code is used to calibrate a second impedance of the one or more pull-down units.

17. The method of claim 16, wherein the first set of calibration units comprises a greater number of transistor sets than the second set of calibration units.

18. The method of claim 17, wherein providing, by the first set of calibration units, the first ZQ calibration code comprises executing a bit shifting operation.

19. The method of claim 16, wherein the second set of calibration units comprises a greater number of transistors sets than the one or more pull-down units of the output buffer.

20. The method of claim 19, wherein providing the second ZQ calibration code to the one or more pull-down units of the output buffer comprises executing a bit shifting operation.
